(19) United States
(12) Patent Application Publication
(10) Pub. No.: US 2007/0295975 A1
(43) Pub. Date: Dec. 27, 2007

(54) Light-Emitting Device

(75) Inventor: Mitsuhiro Omae, Tottori-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: Sanyo Electric Co., LTD., Moriguchi-shi (JP); Tottori Sanyo Electric Co., Ltd., Tottori-shi (JP)

(21) Appl. No.: 11/630,140

(22) PCT Filed: Jun. 23, 2005
(86) PCT No.: PCT/JP05/11565

§ 371 Date: Jul. 9, 2007

(30) Foreign Application Priority Data
Jun. 25, 2004 (JP) 2004-187404
Jul. 22, 2004 (JP) 2004-214333
Jul. 29, 2004 (JP) 2004-22467

(51) Int. Cl. H01L 33/00

(52) U.S. Cl. 257/89; 257/E33.001

(57) ABSTRACT

A light-emitting device (1) is composed by integrating light-emitting diodes (2R, 2G, 2B) and a drive IC (3) for driving these light-emitting diodes (2R, 2G, 2B). The light-emitting device (1) is characterized in that the drive IC (3) has a built-in circuit for controlling the current value of each light-emitting diode (2) or the current proportions of the light-emitting diodes at constant values. The adjustment of the intensities of the light beams emitted from the light-emitting diodes can be simplified, and no outside circuits for adjustment are needed. The structure is excellent in assemblability. When a desired emission color is produced by mixing the emission colors, the adjustment for the mixing is easy, and a structure suited for enhancing the color rendering properties when a while light is emitted is provided.

### FIELD OF THE INVENTION

The present invention relates to a light-emitting device which integrally comprises a light-emitting diode with a drive IC thereof.

### RELATED ART

JP-2001-217463-A discloses a light-emitting device capable of emitting pseudo-white light by combining a light-emitting diode and a fluorescent body which emits light of a complementary color to that of the light-emitting diode. Generally, although devices which emit pseudo-white light by combining a blue light emitting object as the light-emitting device and a yellow light emitting object as the fluorescent body are commonly employed, there is a problem that color rendering properties are lacking as a result of a specific color component being poor (in this case, blue and yellow are mixed, so that the red component is poor).

There are examples which use mixed colors from light-emitting diodes of the three primary colors red, green and blue. However, in the case of emitting white light by mixing the three primary colors, the current adjustment in order to adjust the emitted light level of each of the colors is cumbersome.

Not just when emitting white light, but also in the case of obtaining a desired color or emitted light intensity distribution using a plurality of light-emitting diodes which are the same or different color, the current adjustment in order to adjust the emitted light intensity for each of the light-emitting diodes is cumbersome. While the adjustment can be performed with an external circuit, if an external circuit is provided for each of the individual devices, the circuit configuration becomes complicated.

[Patent Document 1] JP-2001-217463-A

### DISCLOSURE OF THE INVENTION

### Problems to be Solved

It is one aspect of the present invention to provide features which can simplify adjustment of the emitted light intensity from a plurality of light-emitting diodes.

It is another aspect of the present invention to provide features in which an external circuit for adjustment is unnecessary, and which has good assembly workability. It is another aspect of the present invention to provide features in which, when trying to obtain a desired emitted color by mixing a plurality of emitted colors, the adjustment for such mixing is easy.

It is another aspect of the present invention to provide features which is suitable for increasing color-rendering properties when emitting white light. It is another aspect of the present invention to provide a form which is convertible with related-art two-terminal light-emitting devices, even when emitting light by mixing a plurality of colors.

For emitted white light formed from the three primary colors of red, green and blue, a discontinuous region exists in the red and green emitted light spectrum, and thus the emitted light is not perfectly white. It is another aspect of the present invention to enable continuous white light from red through to blue to be emitted.

In the past, to control the three primary colors of red, green and blue, at least four external terminals were required. It is another aspect of the present invention to enable control by a small number of external terminals (e.g. three), thereby allowing complex color control to be achieved by a small number of external terminals.

### Means to Solve the Problems

A light-emitting device as recited in claim 1 of the present invention includes a plurality of light-emitting diodes and a drive IC integrated with the light-emitting diodes to drive the diodes. The drive IC is embedded with a circuit for controlling at a constant level a current value for each of the plurality of light-emitting diodes or a constant current ratio among the light-emitting diodes. Since the drive IC is embedded with a circuit for controlling at a constant level a current value for each of the plurality of light-emitting diodes or a constant current ratio among the light-emitting diodes, an optimum current ratio can be pre-adjusted among the plurality of light-emitting diodes. As a result, light synthesized from the light beams of the plurality of light-emitting diodes can be maintained in a uniform state.

The light-emitting device as recited in claim 2 is such that the plurality of light-emitting diodes include emitted colors capable of forming white light by mixing light beams thereof. A device suitable for lighting or as a light source can be provided, since the plurality of light-emitting diodes include emitted colors which can form white light by mixing the light beams thereof.

The light-emitting device as recited in claim 3 is such that the plurality of light-emitting diodes include emitted colors of primary colors red, green and blue. Since the plurality of light-emitting diodes include emitted colors of the primary colors of red, green and blue, a white light source having excellent color rendering properties can be provided. If different emitted colors are added to the emitted colors of the three primary colors, color-rendering properties can be increased even further.

The light-emitting as recited in claim 4 is such that the plurality of light-emitting diodes include emitted colors having a complementary relationship. Since the plurality of light-emitting diodes include emitted colors having a complementary relationship, a white light source using two light-emitting diodes can be provided, whereby a reduction in the number of components can be achieved.

The light-emitting device as recited in claim 5 is such that the plurality of light-emitting diodes include different emitted colors. Since the plurality of light-emitting diodes include different emitted colors, when providing a desired color other than white by mixing, the color properties thereof can be maintained at a constant state.

The light-emitting device as recited in claim 6 is such that the plurality of light-emitting diodes include the same emitted color. Since the plurality of light-emitting diodes include the same emitted color, when causing a change in the light quantity distribution from within light-emitting diodes having the same color, setting and retention of the current distribution corresponding to such light quantity distribution becomes possible.

The light-emitting device as recited in claims 7 and 8 is such that at least two of the plurality of light-emitting diodes are connected in series, wherein the at least two light-emitting diodes connected in series are the same color or a different color selected from among red, orange, and yellow light-emitting diodes. By connecting in series a specific diode, such as a light-emitting diode having a small VF and a light-emitting diode which fills in a gap in the spectrum, emission efficiency can be increased, and, spectrum continuity can be increased.

The light-emitting device as recited in claim 9 is such that for the drive IC, a plurality of transistors are connected in series to each light-emitting diode. The current value flowing in the light-emitting diodes can be set individually for each light-emitting diode according to the design of the transistors.

The light-emitting device as recited in claim 10 is such that field effect transistors or bipolar transistors are used for the transistors of the drive IC. As the drive IC, a multi-functional device configuration can be provided.

The light-emitting device as recited in claim 11 is such that gate terminals or base terminals of the transistors of the drive IC are commonly connected. By commonly connecting, the operation timing of each of the transistors can be aligned. In addition, adjustment of the output current value or current ratio becomes easier.

The light-emitting device as recited in claim 12 is such that the gate terminals or base terminals of the transistors of the drive IC are commonly connected to wiring of a light-emitting diode having a highest VF voltage among each of the light-emitting diodes whose current value or current ratio has been adjusted. By connecting in common to the wiring of the light-emitting diode having the highest VF voltage, the light-emitting diode having poor start-up properties can be activated in advance, whereby the operation timing can be aligned.

The light-emitting device as recited in claim 13 is such that the light-emitting device is a two-terminal device which comprises only the two external terminals as terminals connecting externally. Since this is a two-terminal device comprising only two external terminals, a configuration which is convertible with related-art two-terminal light-emitting devices can be provided.

The light-emitting device as recited in claim 14 is such that the drive IC is embedded with a circuit for controlling current value for each of the plurality of light-emitting diodes at a constant level even if the voltage applied between the two external terminals fluctuates, for example by about ±10% from a stipulated value (for a 5 V power source, in a range of 5±0.5 V). According to these features, the current value for each of the plurality of light-emitting diodes can be controlled at a constant level even if the voltage applied between a pair of external terminals fluctuates, whereby the emission state of the plurality of light-emitting diodes can be maintained in a stable manner. As a result, the mixed color state of the light beams of the plurality of light-emitting diodes can be maintained at a constant level.

The light-emitting device as recited in claim 15 is such that the drive IC includes external terminals. By providing external terminals on the drive IC, a reduction in the number of components and the size of the device can be achieved.

The light-emitting device as recited in claim 16 is such that the external terminals are control terminals for varying the current value or current ratio for each of the plurality of light-emitting diodes. By separately providing control terminals, it is possible to selectively use a mode for maintaining a constant mixed color state, and a mode for freely varying the mixed color state according to signals from the external terminals, whereby multi-functionality can be increased.

The light-emitting device as recited in claim 17 is such that the external terminals are connected to a gate terminal or base terminal of a transistor of the drive IC, for allowing the current flowing in each of the light-emitting diodes to be externally controlled. Since the current flowing in the light-emitting diodes can be controlled by the external terminals, the scope of the applied embodiments can be broadened.

The light-emitting device as recited in claim 18 is such that the external terminals are commonly connected to a gate terminal or base terminal of a transistor of the drive IC, for allowing the current flowing in each of the light-emitting diodes to be externally controlled with the same timing. Since control can be performed with the same timing, a reduction in the number of terminals can be achieved.

The light-emitting device as recited in claim 19 is such that the external terminals, without any relationship to driving of a transistor of the drive IC, are connected individually and controllably with each of the light-emitting diodes. Since the current flowing in the light-emitting diodes can be controlled by the external terminals, the scope of the applied embodiments can be broadened.

The light-emitting device as recited in claim 20 is such that the drive IC includes a current supply circuit for supplying a standard current, and a driver circuit which receives a current supply from the current supply circuit for supplying a current which is set for each of the light-emitting diodes, and wherein the external terminals are connected so that operation of the driver circuit can be externally controlled. By including a driver circuit, it is easier to set various current values based on a standard current supplied from a current supply circuit.

The light-emitting device as recited in claim 21 is such that the drive IC includes a function for fine-tuning the current value for each of the plurality of light-emitting diodes or a current ratio for each of the light-emitting diodes. By including a function for fine-tuning the current ratio, fluctuation in output due to, for instance, differences in the initial characteristics of the light-emitting diodes or the drive IC can be suppressed by the fine-tuning.

The light-emitting device as recited in claim 22 is such that the drive IC includes a non-volatile memory for storing correction data, and a control circuit for controlling operation of the driver circuit based on data stored in the memory and data sent from the external terminals. By storing correction data in a non-volatile memory, it is possible to electrically correct differences in characteristics. Correction can be repeatedly carried out each time a difference in characteristics occurs.

The light-emitting device as recited in claim 23 is such that the drive IC fine-tunes the current value for each of the plurality of light-emitting diodes based on data stored in the memory. Since the current value for each of the light-emitting diodes is fine-tuned based on data stored in the memory, the output of the light-emitting diodes can be controlled to a higher degree of accuracy.

The light-emitting device as recited in claim 24 is such that the fine-tuning is performed by laser trimming a disconnection region provided on a surface of the drive IC, or performed by zapping a disconnection region provided inside the drive IC. By fine-tuning with laser trimming or zapping, fine-tuning operability can be increased.

The light-emitting device as recited in claim 25 is such that the fine-tuning is performed by selecting whether a wire bond is present or not with respect to one or more wire bond terminals provided on a surface of the drive IC. Since the fine-tuning is performed by selecting whether a wire bond is present or not, fine-tuning operability can be increased.

The light-emitting device as recited in claim 26 is such that the plurality of light-emitting diodes and the drive IC are mounted on a circuit board. Since the plurality of light-emitting diodes and the drive IC are mounted on a circuit board, a device configuration which utilizes a multi-functional circuit board can be employed, whereby production operability increases.

The light-emitting device as recited in claim 27 is such that the plurality of light-emitting diodes are disposed on the drive IC. Since the plurality of light-emitting diodes are disposed on the drive IC, the plurality of light-emitting diodes and the drive IC can be assembled in advance, thereby increasing assemble operability. Further, the surface area of the device can be made smaller, whereby a reduction in device size can be achieved.

The light-emitting device as recited in claim 28 is such that the plurality of light-emitting diodes and the drive IC are covered by the same resin. By covering with a resin, both these elements can be protected, and the light extraction efficiency of the plurality of light-emitting diodes can be increased.

### ADVANTAGES OF THE INVENTION

According to the present invention, features can be provided which can simplify the various adjustment operations of a plurality of light-emitting diodes; a device configuration can be provided which has good assembly workability; color rendering properties when emitting white light can be increased; and, a form can be provided which is convertible with related-art two-terminal light-emitting devices, even when mixing a plurality of colors.

### BRIEF DESCRIPTION OF THE DRAWINGS

FIG. 1 is a perspective view as seen through the molded resin of a light-emitting device of the first embodiment.

FIG. 2 is a cross-sectional view taken along the line II-II of FIG. 1.

FIG. 3A is a circuit diagram of the light-emitting device of the first embodiment, and FIG. 3B is an equivalent circuit schematic.

FIG. 4 is a detailed circuit diagram of the light-emitting device of the first embodiment.

FIG. 5 is a timing chart illustrating the operation of the light-emitting device of the first embodiment.

FIG. 6 is a perspective view as seen through the molded resin of a light-emitting device of the second embodiment.

FIG. 7 is a cross-sectional view taken along the line VII-VII of FIG. 6.

FIG. 8 is a perspective view as seen through the molded resin of a light-emitting device of the third embodiment.

FIG. 9 is a cross-sectional view taken along the line IX-IX of FIG. 8.

FIG. 10 is a perspective view as seen through the molded resin of a light-emitting device of the fourth embodiment.

FIG. 11 is a cross-sectional view taken along the line XI-XI of FIG. 10.

FIG. 12 is a perspective view of a light-emitting device of the second embodiment.

FIG. 13 is a cross-sectional view taken along the line XIII-XIII of FIG. 12.

FIG. 14 is a perspective view illustrating the placement of the light-emitting diodes and the drive IC shown in FIG. 13.

FIG. 15 is a perspective view as seen through the molded resin of a light-emitting device of the sixth embodiment.

FIG. 16 is a cross-sectional view taken along the line XVI-XVI of FIG. 15.

FIG. 17 is a detailed circuit diagram of the light-emitting device of the seventh embodiment.

FIG. 18 is a detailed circuit diagram of the light-emitting device of the eighth embodiment.

FIG. 19A is a circuit diagram of the light-emitting device according to the ninth embodiment, and FIG. 19B is an equivalent circuit schematic.

FIG. 20 is a detailed circuit diagram of the light-emitting device of the ninth embodiment.

FIG. 21 is a circuit diagram of the light-emitting device according to the tenth embodiment.

FIG. 22 is a circuit diagram of the light-emitting device according to the eleventh embodiment.

FIG. 23A is a schematic circuit diagram of the light-emitting device according to the twelfth embodiment, and FIG. 23B is a detailed circuit diagram of the light-emitting device according to the twelfth embodiment.

FIG. 24 is a timing chart illustrating the operation of the light-emitting device according to the twelfth embodiment.

FIG. 25 is a perspective view as seen through the molded resin of light-emitting device according to the twelfth embodiment.

FIG. 26A is a schematic circuit diagram of the light-emitting device according to the thirteenth embodiment, and FIG. 26B is a detailed circuit diagram of the light-emitting device according to the thirteenth embodiment.

FIG. 27 is a timing chart illustrating the operation of the light-emitting device according to the thirteenth embodiment.

FIG. 28 is a perspective view as seen through the molded resin of light-emitting device according to the thirteenth embodiment.

FIG. 29A is a schematic circuit diagram of the light-emitting device according to the fourteenth embodiment, and FIG. 29B is a detailed circuit diagram of the light-emitting device according to the fourteenth embodiment.

FIG. 30 is a timing chart illustrating the operation of the light-emitting device according to the fourteenth embodiment.

FIG. 31 is a perspective view as seen through the molded resin of light-emitting device according to the fourteenth embodiment.

FIG. 32A is a schematic circuit diagram of the light-emitting device according to the fifteenth embodiment, and FIG. 32B is a detailed circuit diagram of the light-emitting device according to the fifteenth embodiment.

FIG. 33 is a timing chart illustrating the operation of the light-emitting device according to the fifteenth embodiment.

FIG. 34 is a perspective view as seen through the molded resin of light-emitting device according to the fifteenth embodiment.

FIG. 35A is a schematic circuit diagram of the light-emitting device according to the sixteenth embodiment, and FIG. 35B is a detailed circuit diagram of the light-emitting device according to the sixteenth embodiment.

FIG. 36 is a timing chart illustrating the operation of the light-emitting device according to the sixteenth embodiment.

FIG. 37A is a schematic circuit diagram of the light-emitting device according to the seventeenth embodiment, and FIG. 37B is a detailed circuit diagram of the light-emitting device according to the seventeenth embodiment.

FIG. 38 is a detailed circuit diagram of the light-emitting device according to the eighteenth embodiment.

FIG. 39 is a detailed circuit diagram of a modified example of the light-emitting vice according to the eighteenth embodiment.

FIG. 40 is a detailed circuit diagram of another modified example of the light-emitting device according to the eighteenth embodiment.

FIG. 41 is a detailed circuit diagram of yet another modified example of the light-emitting device according to the eighteenth embodiment.

FIG. 42 is a detailed circuit diagram of yet another modified example of the light-emitting device according to the eighteenth embodiment.

FIG. 43 is a detailed circuit diagram of yet another modified example of the light-emitting device according to the eighteenth embodiment.

FIG. 44 is a detailed circuit diagram of yet another modified example of the light-emitting device according to the eighteenth embodiment.

FIG. 45A is a circuit diagram of the light-emitting device 1α of the nineteenth embodiment corresponding to FIG. 37B; and FIG. 45B is a circuit diagram illustrating the details of the portion relating to the red light-emitting diode 2R.

### REFERENCE NUMERALS

1 Light-emitting device
2 Light-emitting diode
3 Drive IC
4 Circuit board
5 External terminal
6 External terminal
7 Molded resin
8 Frame
9 Resin

### DESCRIPTION OF THE PREFERRED EMBODIMENTS

Embodiments of the present invention will now be described with reference to the drawings.

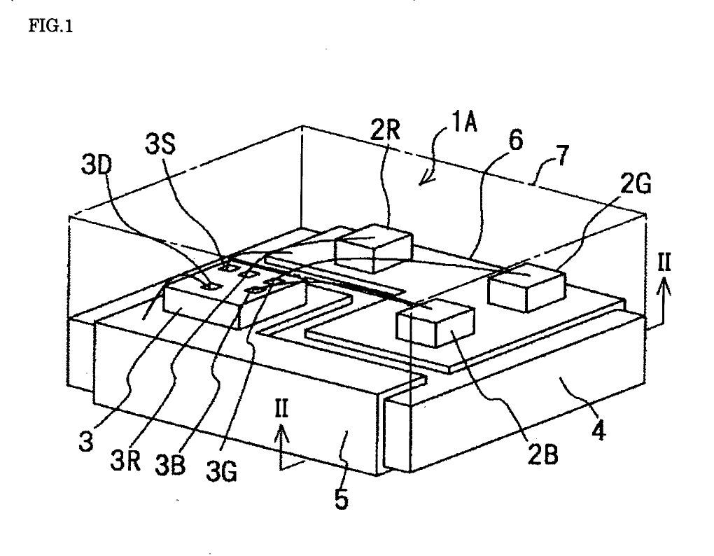

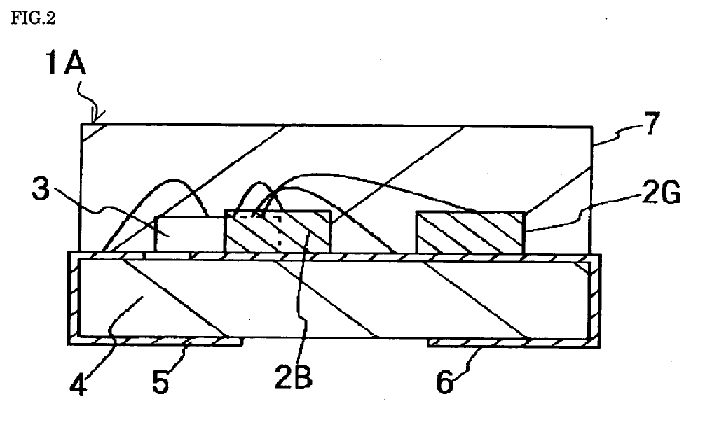

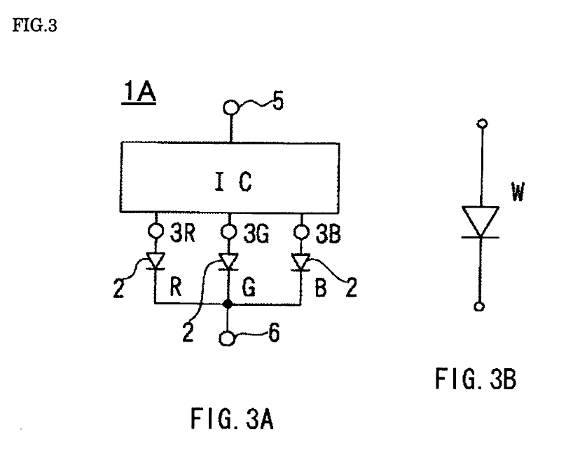

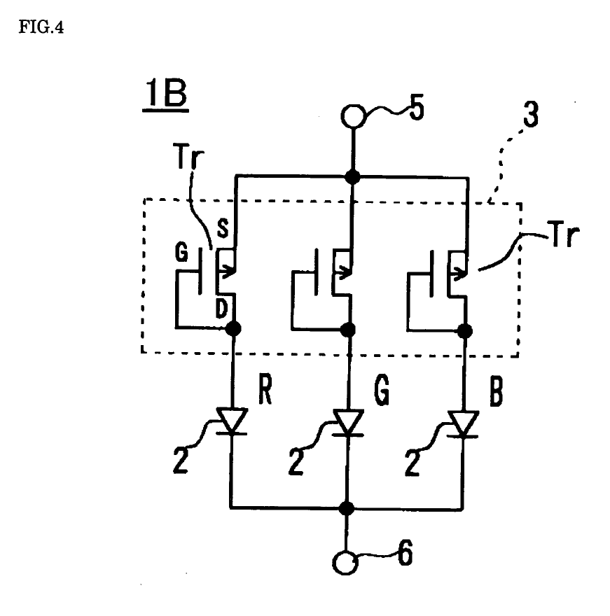

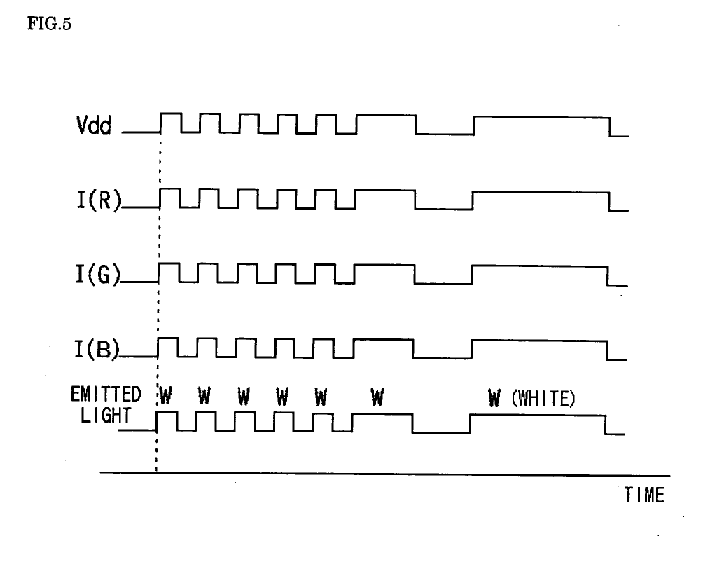

First, a light-emitting device LA according to a first embodiment will be described with reference to FIGS. 1 to 5. FIG. 1 is a perspective view as seen through the molded resin of light-emitting device 1A; FIG. 2 is a cross-sectional view taken along the line II-II of FIG. 1; FIG. 3A is a circuit diagram of the light-emitting device 1A; FIG. 3B is an equivalent circuit schematic; FIG. 4 is a detailed circuit diagram of the light-emitting device 1A; and FIG. 5 is a timing chart illustrating the operation of the light-emitting device 1A.

The light-emitting device 1A is configured such that a plurality of chip-state light-emitting diodes 2 and a drive IC 3 for driving these light-emitting diodes 2 are integrated on a circuit board 4. The light-emitting diodes 2 are configured from bare chips which have been cut-out from a wafer, and comprise three light-emitting diodes 2R, 2G and 2B which have emitted colors of the three primary colors of red (R), green (G) and blue (B) in order to emit white light.

On the surface of the drive IC 3 are provided output terminals 3R, 3G and 3B which correspond with the respective light-emitting diodes 2R, 2G and 2B. A drive circuit for controlling the current value for each of the light-emitting diodes 2R, 2G and 2B, or for controlling the current ratio among the light-emitting diodes 2R, 2G and 2B, at a constant level is also embedded in the drive IC 3. This drive circuit adjusts the output current of each output terminal, whereby the emitted light intensity of each of the light-emitting diodes 2R, 2G and 2B is maintained within a respective preset range. In the drive IC 3, the current value for each output or the current ratio is preset so that white light can be obtained by the mixing of the emitted colors from the three light-emitting diodes 2R, 2G and 2B.

The light-emitting device 1A is a two-terminal type light-emitting device, in which two external terminals 5, 6 are provided on a circuit board 4. The drive IC 3 is fixedly disposed by a conductive material or an insulating material on the external terminal 5 which functions as the anode, and the light-emitting diodes 2R, 2G and 2B are fixedly disposed by a conductive material on the external terminal 6 which functions as the cathode.

The light-emitting diodes 2 and drive IC 3 are fixedly disposed on the circuit board 4 so as to be respectively positioned at the four corners of a rectangle. The drive IC 3 is provided with terminals such as power terminals 3D, 3S and output terminals 3R, 3G and 3B on its surface. These terminals electrically connect the external terminals 5, 6 and the light-emitting diodes 2R, 2G and 2B by metal wires or the like.

Since all of the terminals on the drive IC 3 are drawn out from the surface side, the underside can be fixed by an insulating material onto the external terminal 5 or an insulating base material of the circuit board 4. However, in the case where the underside of the drive IC 3 is configured by an N-type semiconductor substrate, the underside can also be fixed to the external terminal 5 by a conductive material. Since the light-emitting diodes 2 are provided with a cathode electrode on the underside, the light-emitting diodes 2 can be fixed on the external terminal 6 by a conductive material. However, in the case where both the anode and the cathode are provided on the surface of the light-emitting diodes 2, there is a need to provide wiring with a wire to both of these electrodes.

The circuit board 4 is configured by a print board, which uses an insulating material such as glass epoxy or polyimide as a base, on which a conductive pattern is formed on the surface and the underside from printed wiring or the like. The external terminals 5, 6 are configured from this conductive pattern.

The light-emitting diodes 2 and drive IC 3 are fixed onto a circuit board having large surface area which comprises a plurality of patterns individually corresponding to a plurality of light-emitting devices. Once the wiring has been provided thereon, the light-emitting diodes 2 and drive IC 3 are covered by a light-permeable resin 7. The light-emitting diodes 2 and drive IC 3 are then discretely cut up using cutting methods such as a dicing saw or the like, whereby a plurality of light-emitting devices 1A can be fabricated.

As illustrated in FIG. 3A, the light-emitting device 1A has a circuit configuration wherein a light-emitting circuit forming of a drive IC 3 and light-emitting diodes 2 connected therewith is connected between two external terminals 5, 6. The external terminals 5, 6 are used by connecting to corresponding terminals of a not-shown circuit. If a constant voltage or a constant current is applied between the external terminals 5, 6, the drive IC 3 is activated, and a current value preset for each of the light-emitting diodes 2R, 2G and 2B, or a current having a ratio preset (e.g. a ratio of 2:2:1) for each of the light-emitting diodes 2R, 2G and 2B, is applied. This current causes the respective light-emitting diodes 2R, 2G and 2B to emit red, green and blue light. These beams of light become mixed in the emitted-light pathway, to thereby form white light. Therefore, an equivalent circuit schematic of such a light-emitting device 1A is like that illustrated in FIG. 3B, and is equivalent to a device comprising one white light emitting diode between the external terminals 5, 6.

As illustrated in FIG. 4, the drive IC 3 is configured from a plurality of transistors Tr for applying the preset constant current to each of the light-emitting diodes 2R, 2G and 2B. These transistors Tr can be configured from a MOS type FET, for instance. In the present embodiment, a P-channel MOSFET is connected between the source (S) and drain (D) terminals, and is used in a connected state with a reverse voltage applied. By connecting the drain side of each of the transistors Tr with the anode side of each of the light-emitting diodes 2R, 2G and 2B, the transistors Tr and the light-emitting diodes 2 are connected in series, and these series circuits are connected in parallel to the external terminals 5, 6. The gate (G) terminal of each of the transistors Tr is connected to a connecting portion of the light-emitting diodes 2 and the transistors Tr.

The light-emitting device 1A is used by connecting the external terminals 5, 6 to corresponding terminals of a not-shown circuit. As illustrated in FIG. 5, if a constant voltage Vdd or a constant current is applied between the external terminals 5, 6, the drive IC 3 is activated, and a current I(R), I(G) and I(B) having a ratio (e.g. a ratio of 2:2:1) that is preset for each of the light-emitting diodes 2R, 2G and 2B, is applied to each of the light-emitting diodes. This current ratio can be preset, for example, depending on the surface ratio of the transistors Tr. In the circuit illustrated in FIG. 3, if the voltage applied between the external terminals 5, 6 fluctuates, the current flowing in each of the light-emitting diodes also fluctuates. However, because the current ratio stays the same, there is little fluctuation in the mixed color state.

This current I(R), I(G) and I(B) cause the respective light-emitting diodes 2R, 2G and 2B to emit red, green and blue light. These beams of light become mixed in the emitted-light pathway, to thereby form white light (W). Therefore, an equivalent circuit schematic of such a light-emitting device 1A is like that illustrated in FIG. 3B, and is equivalent to a device comprising one white light emitting diode between the external terminals 5, 6.

Thus, despite the fact that the light-emitting device 1 only comprises two external terminals 5, 6, white light can be emitted from the mixing of red, green and blue light, thereby allowing white light to be emitted while having a structure that is convertible with related-art one-chip type light-emitting devices.

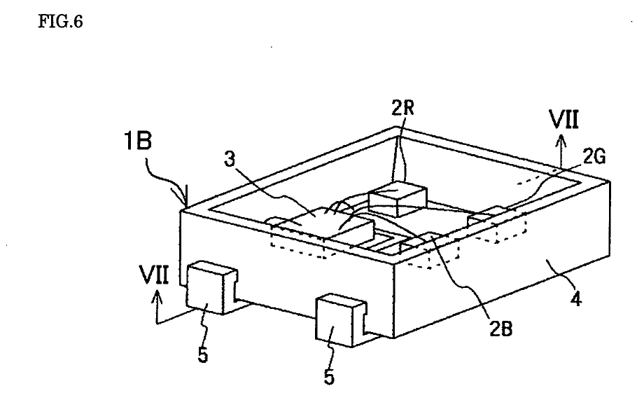

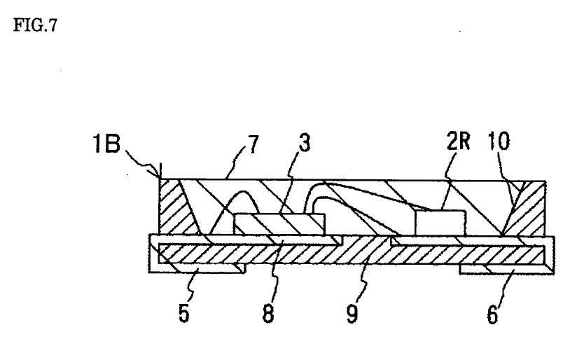

Next, the light-emitting device 1B according to a second embodiment will be described with reference to FIGS. 6 and 7. FIG. 6 is a perspective view as seen through the molded resin of light-emitting device 1B; and FIG. 7 is a cross-sectional view taken along the line VII-VII of FIG. 6. Structural elements which are the same as those of light-emitting device 1A in the first embodiment will be explained below using the same reference numerals.

The major difference between the light-emitting device 1B according to the second embodiment and the light-emitting device 1A of the first embodiment is that a board which employs a lead frame is used instead of a print-type board (the other features basically being the same). The board 4 is formed with a metal lead frame 8, in which plating was coated onto an iron or copper material, integrated with a resin 9. The lead frame 8 is configured from a pair of frames comprising an inner section that functions as a component placement region and an outer section which functions as an external terminal, these sections being integrated with the resin 9 by a process such as insert molding. The outer section of the frame 8 is, after being cut away from the lead frame, folded as necessary onto the underside of the resin, to thereby function as the external terminals 5, 6. The surface of the inner on which the light-emitting diodes 2 and drive IC 3 are supposed to be disposed is exposed without being covered by the resin 9. The resin 9 constituting the circuit board 4 also functions as a reflective frame which reflects the light of the light-emitting diodes 2. So as to function as a reflective frame, it is preferable to use as the resin 9 a white resin having excellent reflectivity. To increase the performance of the reflective frame, it is also preferable to provide a reflective wall 10 for reflecting light upwards in the circuit board 4 periphery. In the hollow surrounded by this reflective wall 10, the light-emitting device 1B is formed by providing a resin 7 for molding the light-emitting diodes 2 and the drive IC 3. The circuit configuration is the same as that illustrated in FIG. 3A.

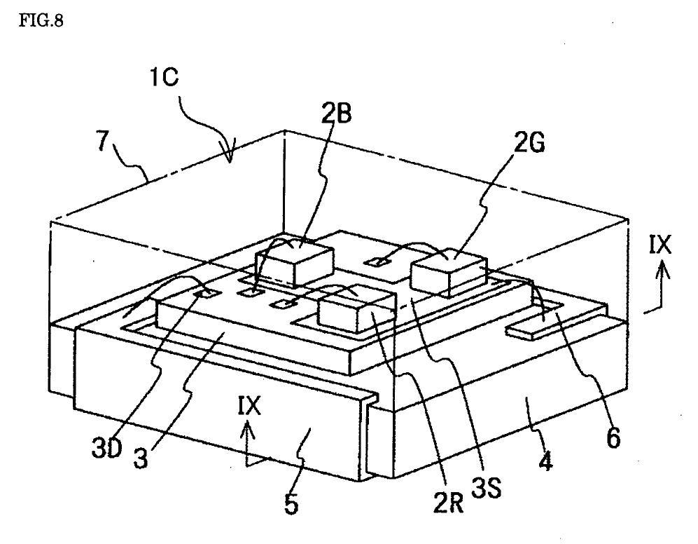

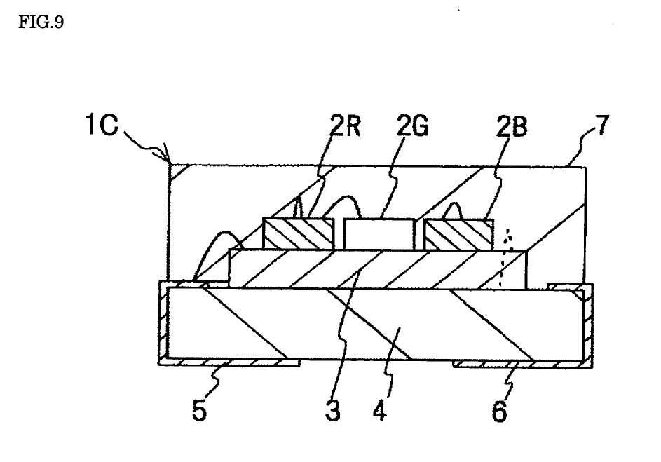

Next, a light-emitting device 1C according to a third embodiment will be described with reference to FIGS. 8 and 9. FIG. 8 is a perspective view as seen through the molded resin of light-emitting device 1C; and FIG. 9 is a cross-sectional view taken along the line IX-IX of FIG. 8.

The major difference between the light-emitting device 1C according to the third embodiment and the light-emitting device 1A of the first embodiment is that the light-emitting diodes 2 disposed on the circuit board 4 are disposed on the drive IC 3 (the other features basically being the same). The drive IC 3 is fixed by an insulating material or a conductive material on the circuit board 4, and is electrically connected with the external terminals 5, 6 by a wire. In the present embodiment, the drive IC 3 is fixed on an insulating base material of the circuit board 4. The cathode side of the light-emitting diodes 2R, 2G and 2B is fixed by a conductive material onto the terminal for the cathode formed on the surface of the drive IC 3, and the anode side of the light-emitting diodes is connected by a wire to the output terminals 3R, 3G and 3B formed on the surface of the drive IC 3.

As with the previous embodiments, the drive IC 3 is activated by receiving a constant voltage or a constant current supply from the pair of power terminals 3D, 3S, whereby a preset current is applied to each of the light-emitting diodes 2R, 2G and 2B. This current supply causes the respective light-emitting diodes 2R, 2G and 2B to emit light in their specified color. These beams of light become mixed, whereby, in this embodiment, the emission of white light can be obtained.

Thus, for the present embodiment as well, and as with the previous embodiments, despite the fact that the light-emitting device 1C only comprises two external terminals 5, 6, white light can be emitted from the mixing of red, green and blue light, thereby allowing white light to be emitted while having a structure that is convertible with related-art one-chip type light-emitting devices. Since in most cases the drive IC 3 is made from silicon, thermal conductivity is better than glass epoxy, whereby heat-radiating properties can be increased. In addition, since the difference in thermal expansion coefficient with the semiconductor material constituting the light-emitting diodes 2 can be reduced, stress and strain caused by thermal expansion coefficient differences can be suppressed, thereby enabling greater reliability.

The features which dispose the light-emitting diodes 2 on the drive IC 3 can be applied to embodiments other than the first embodiment. For example, such features can be applied to other embodiments including the second embodiment.

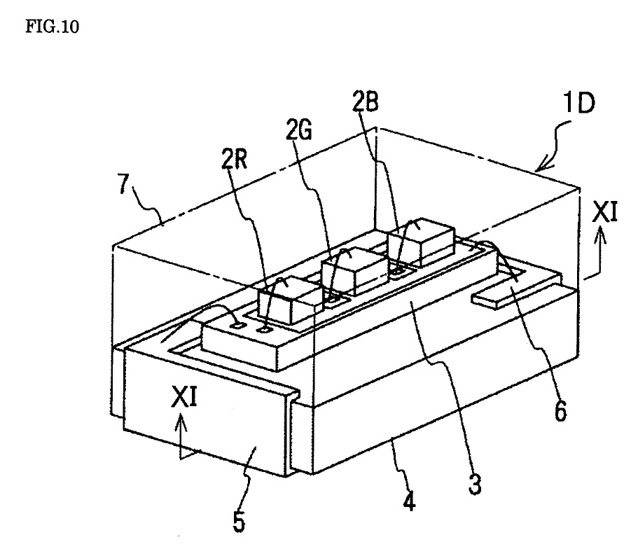

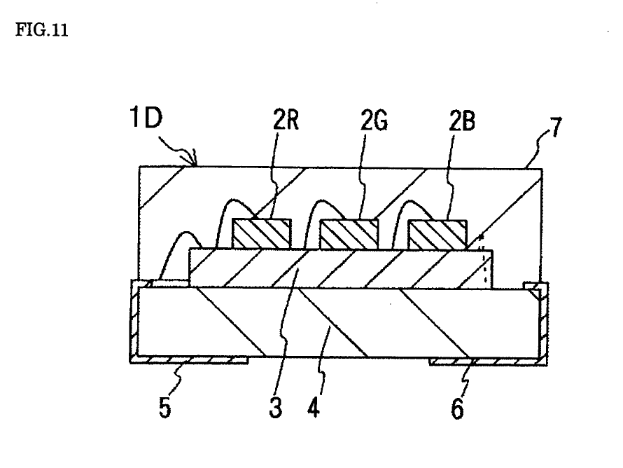

Next, a light-emitting device 1D according to a fourth embodiment will be described with reference to FIGS. 10 and 11. FIG. 10 is a perspective view as seen through a molded resin 7 of the light-emitting device 1 according to the fourth embodiment; and FIG. 11 is a cross-sectional view taken along the line XI-XI of FIG. 10.

The major difference between the light-emitting device 1D according to the fourth embodiment and the light-emitting device 1C of the third embodiment is that the plurality of light-emitting diodes 2R, 2G and 2B disposed on the drive IC 3 are disposed in a single line (the other features basically being the same). By disposing the plurality of light-emitting diodes 2R, 2G and 2B in a single line, a slim light-emitting device 1 having a narrow width can be provided.

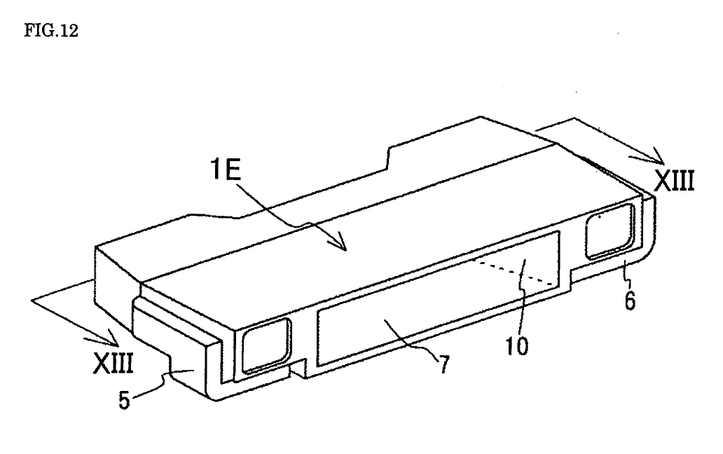

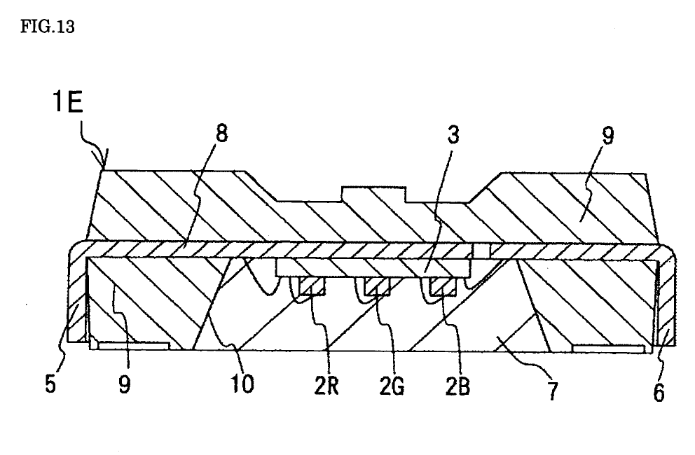

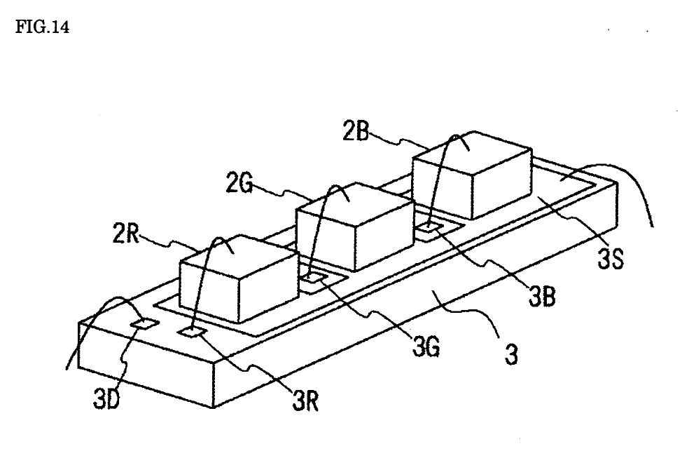

Next, a fifth light-emitting device 1E will be described with reference to FIGS. 12 to 14. FIG. 12 is a perspective view of the light-emitting device 1E according to the fifth embodiment; FIG. 13 is a cross-sectional view taken along the line XIII-XIII of FIG. 12; and FIG. 14 is a perspective view illustrating the placement of the light-emitting diodes and the drive IC shown in FIG. 13.

The light-emitting diodes of the first to fourth embodiments have a top view structure wherein light is extracted in a perpendicular direction to the board on which the light-emitting devices 1A to 1D are attached. In contrast, the fifth embodiment has different basic features, in that the light-emitting device 1E has a side view structure wherein light is extracted in a parallel direction to the board on which the light-emitting device 1E is attached. The circuit board 4 of this embodiment has the same structure as the lead frame type board light-emitting device 1 according to the second embodiment, wherein a lead frame 8 is formed in an integrated manner with a resin 9 by insert molding or similar method. The placement of the light-emitting diodes 2 and drive IC 3 is the same as in the fourth embodiment, wherein the light-emitting diodes 2R, 2G and 2B on the drive IC 3 are disposed in one line. The placement of the light-emitting diodes 2 and drive IC 3 can, in addition to that of the fourth embodiment, employ the same placement as that of the first to third embodiments or other embodiments.

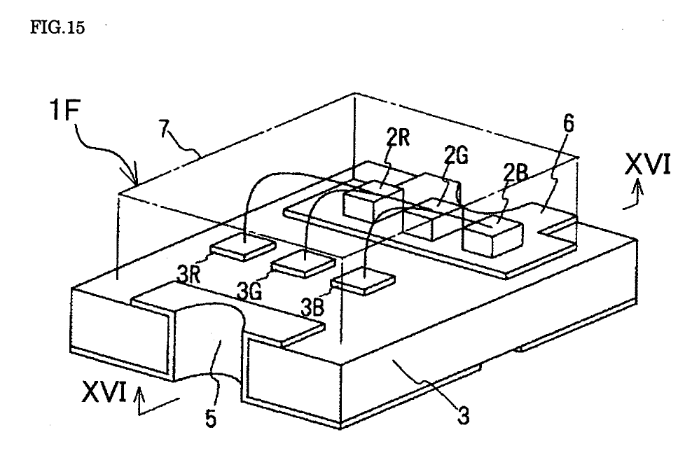

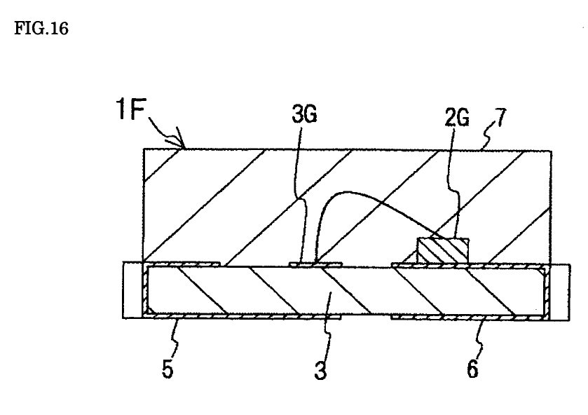

Next, a light-emitting device IF according to a sixth embodiment will be described with reference to FIGS. 15 and 16. FIG. 15 is a perspective view as seen through the molded resin 7 of light-emitting device IF according to the sixth embodiment; and FIG. 16 is a cross-sectional view taken along the line XVI-XVI of FIG. 15.

The major difference between the light-emitting device IF according to the sixth embodiment and the light-emitting devices 1C, 1D of the third and fourth embodiments is that the circuit board 4 is omitted by providing the external terminals 5, 6, which were provided on the circuit board 4, on the drive IC 3. That is, the sixth embodiment includes forming of the pair of external terminals 5, 6 on a pair of side faces of the drive IC 3. The external terminals 5, 6 are not only formed on the side faces of the drive IC 3, but are also formed on the surface and the rear face. In the internal circuit of the drive IC 3, an insulating film for insulating from the external terminals 5, 6 is interposed in the regions which require electrical insulation from the external terminals 5, 6. One of the external terminals 5, 6 is made the cathode, and is connected by a conductive material to the cathode of each of the light-emitting diodes 2R, 2G and 2B located thereabove. The anode of each of the light-emitting diodes 2R, 2G and 2B is connected via wires to the output electrodes 3R, 3G and 3B of the drive IC. The line of light-emitting diodes 2R, 2G and 2B is disposed orthogonal to the array of external terminals 5, 6. The line of output electrodes 3R, 3G and 3B is disposed in between the external terminals 5, 6. By positioning in this manner, the planar shape of the light-emitting device 1 can be made to approximate a square shape. A light-permeable resin 7 is molded on the surface of the drive IC 3 so as to cover the light-emitting diodes 2R, 2G and 2B and wiring thereof. Thus, by using a configuration in which the external terminals 5, 6 are directly formed on the drive IC 3, the light-emitting device IF can be made more compact.

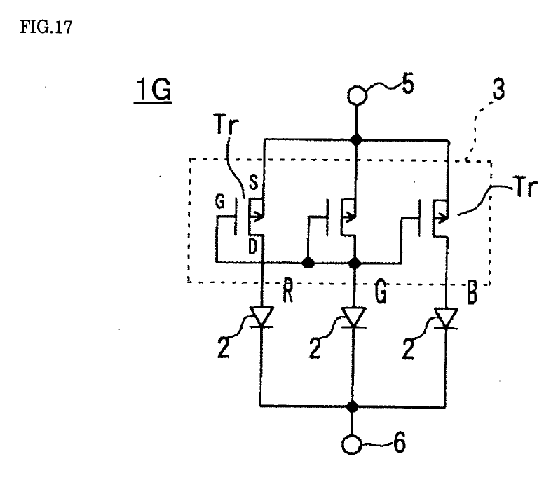

Next, a light-emitting device 1G according to a seventh embodiment will be described with reference to FIG. 17. The light-emitting device 1G according to the seventh embodiment has the same basic features as the light-emitting device 1A of the first embodiment, and thus explanation will focus on the portions that are different. The difference between the light-emitting device 1G according to the seventh embodiment and the light-emitting device 1A of the first embodiment is the internal configuration of the drive IC 3, which is different in the connection configuration of the gate terminal of each of the transistors Tr. In the previous embodiments, the gate terminal of each of the transistors Tr was connected to its respective drain terminal. However, in the present embodiment, the gate terminals of each of the transistors Tr are connected together, wherein their connection point is connected to a preset light-emitting diode 2 and a transistor Tr series circuit. The connection point of the commonly-connected gate terminals is selected based on the VF (forward voltage) of the light-emitting diode. To obtain white light, in the case of applying a respective current of 40 mA, 40 mA and 20 mA to the light-emitting diodes 2R, 2G and 2B, the VF for each diode is 1.95 V, 4.3 V and 3.8 V. The VF of the green light-emitting diode 2 is the highest. However, a higher VF results in a slower current start-up, whereby the emission timing becomes uneven. In view of this, the commonly-connected gate terminals are connected to a series circuit of the light-emitting diode 2 whose VF increases the most, in order to speed up the current start-up of that circuit. As a result, it is easier to align the emission timing of each of the light-emitting diodes 2. In addition, by simultaneously connecting the gate terminals to a common potential, the current value or current ratio flowing in each of the light-emitting diodes 2R, 2G and 2B can be more precisely controlled.

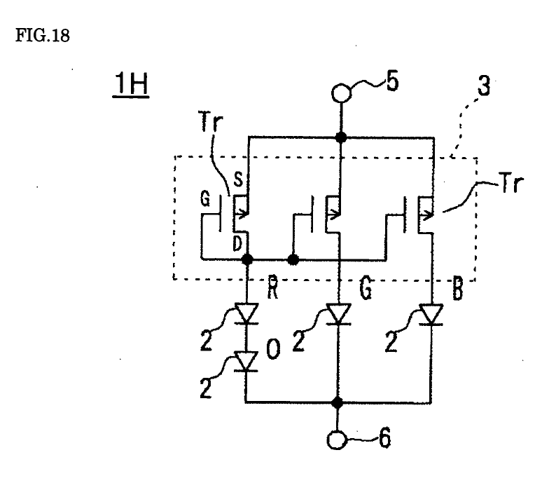

Next, a light-emitting device 1H according to an eighth embodiment will be described with reference to FIG. 18. The light-emitting device 1H according to the eighth embodiment has the same basic features as the light-emitting device 1A according to the first embodiment, and thus explanation will focus on the portions that are different. The difference between the light-emitting device 1H according to the eighth embodiment and the light-emitting device 1A according to the first embodiment is that another light-emitting diode is connected in series to a given light-emitting diode. In the present embodiment, an orange light-emitting diode 20 is connected in series to the red light-emitting diode 2R.

To obtain white light, in the case of applying a respective current of 10 mA to each of the light-emitting diodes 2R, 2O, 2G and 2B, the VF for each diode is 1.85 V, 1.85 V, 3.4 V and 3.4 V. Connecting the light-emitting diodes 2R and 20 in series, whereby their combined VF is 3.7 V, enables the difference with the 3.4 V of the other light-emitting diodes to be reduced. Thus, by connecting the light-emitting diode having the lowest VF from among the three light-emitting diodes of red, green and blue, in series to the other light-emitting diode to thereby adjust the VF to an equivalent value, the load voltage to each of the transistors can be made approximately the same. Further, the power that was being wastefully consumed inside the transistors in the case where there was only a red light-emitting diode, can be effectively utilized by the light-emitting diode 2O, whereby emission efficiency can be increased. Other than orange, other diodes may be selected as the diode connected in series, such as red, yellow or the like.

Generally, the spectral distribution characteristics of RGB light-emitting diodes are such that the peak wavelength of the green light-emitting diode is greatly biased towards the blue light-emitting diode side rather than at the mid point between the blue and red peak wavelengths, so that a region exists wherein the wavelengths are discontinuous between the green and red light-emitting diodes. Nevertheless, as described above, by adding an orange light-emitting diode having a peak wavelength between that of the red and green light-emitting diodes, the wavelength discontinuous region can be filled in, whereby color-rendering properties can be increased. As the added light-emitting diode, other light-emitting diodes can be employed, such as a yellow light-emitting diode or the like, other than orange, as long as such diode has a peak wavelength in between the emitted peak wavelength of the red and green light-emitting diodes. Operation of the light-emitting device 1H according to the eighth embodiment is the same as that for the light-emitting device 1A according to the first embodiment, and is conducted in accordance with the timing chart illustrated in FIG. 5.

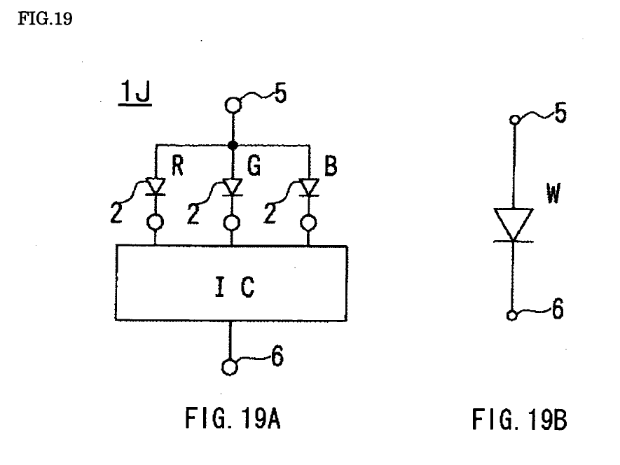

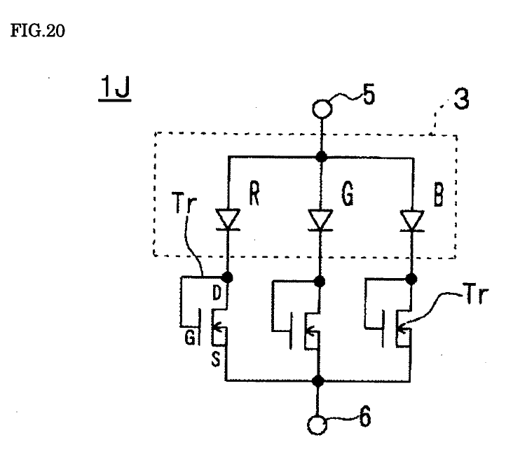

Next, a light-emitting device 1J according to a ninth embodiment will be described with reference to FIGS. 19 and 20. The light-emitting device 1J according to the ninth embodiment has the same basic features as the light-emitting device 1A according to the first embodiment, and thus explanation will focus on the portions that are different. The differences between the light-emitting device 1J according to the ninth embodiment and the light-emitting device 1A according to the first embodiment are the internal configuration of the drive IC 3 and the connection configuration of the light-emitting diodes and the drive IC 3. In the previous embodiments, the drive IC was connected to the anode side of the light-emitting diodes. However, in the present embodiment, the drive IC is connected to the cathode side of the light-emitting diodes. Along with this change in the connection configuration, the drive IC transistors Tr are configured by an N-channel MOSFET, and are used in a connection state of applying a forward bias. Operation of the light-emitting device 1J according to the ninth embodiment is the same as that for the light-emitting device 1A according to the first embodiment, and is conducted in accordance with the timing chart illustrated in FIG. 5.

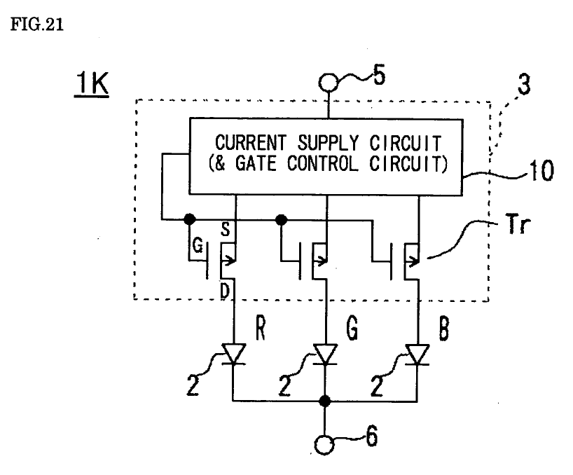

Next, a light-emitting device 1K according to a tenth embodiment will be described with reference to FIG. 21. The light-emitting device 1K according to the tenth embodiment has the same basic features as the light-emitting device 1A according to the first embodiment, and thus explanation will focus on the portions that are different. The difference between the light-emitting device 1K according to the tenth embodiment and the light-emitting device 1A according to the first embodiment is that, as illustrated in FIG. 21, in order to apply a preset constant current to each of the light-emitting diodes 2R, 2G and 2B, the drive IC 3 is configured by a current supply circuit 10 and a plurality of transistors Tr. The current supply circuit 10 is configured from a constant current circuit for supplying a constant current that has been present for each of the plurality of transistors Tr, and is also embedded with a gate control circuit for controlling the gates of the plurality of transistors Tr. The transistors Tr can be configured from a MOS-type FET, for instance. In the present embodiment, a P-channel MOSFET is used. By connecting the drain side of each of the transistors Tr with the anode side of the respective light-emitting diodes 2R, 2G and 2B, the transistors Tr and the light-emitting diodes 2 are connected in series. The gate (G) terminals of each of the transistors Tr are commonly connected, and are connected to the gate control circuit of the current supply circuit 10. The gate control circuit of the current supply circuit 10 is configured so that if a voltage Vdd is applied, a signal is outputted for turning on the transistors Tr.

The light-emitting device 1K according to the tenth embodiment is used by connecting the external terminals 5, 6 to the corresponding terminal of a not-shown circuit. If a constant voltage Vdd is applied between the external terminals 5, 6, the drive IC 3 is activated, and the preset constant current value I(R), I(G) and I(B) preset for each of the light-emitting diodes 2R, 2G and 2B, 40 mA, 40 mA and 20 mA for example, is applied to each of the light-emitting diodes 2. This current value can be preset depending on the current supply circuit 10 and each of the transistors Tr. In the circuit illustrated in FIG. 21, if the voltage applied between the external terminals 5, 6 slightly fluctuates, for example by about ±10% from a stipulated value, even if fluctuating by 5±0.5 V for a 5 V power source, the current values respectively outputted from the current supply circuit 10 are kept constant. This allows the current value and the current ratio flowing to each of the light-emitting diodes 2R, 2G and 2B to be kept the same, whereby as a result the mixed state of the light hardly fluctuates. Operation of the light-emitting device 1K according to the tenth embodiment is the same as that for the light-emitting device 1A according to the first embodiment, and is conducted in accordance with the timing chart illustrated in FIG. 5.

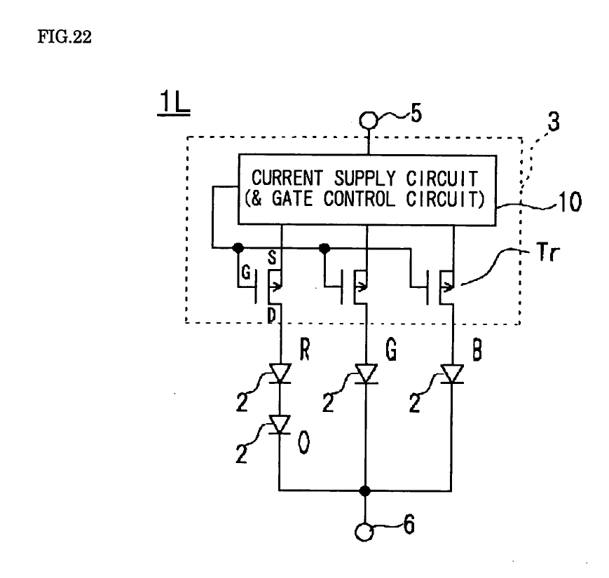

Next, a light-emitting device 1L according to an eleventh embodiment will be described with reference to FIG. 22. The light-emitting device 1L according to the eleventh embodiment has the same basic features as the light-emitting device 1K according to the tenth embodiment, and thus explanation will focus on the portions that are different. The difference between the light-emitting device 1L according to the eleventh embodiment and the light-emitting device 1K according to the tenth embodiment is that another light-emitting diode is connected in series to a given light-emitting diode. In the present embodiment, in the same manner as for the light-emitting device 1H according to the eighth embodiment, an orange light-emitting diode 20 is connected in series to the red light-emitting diode 2R.

For the light-emitting device 1L according to the eleventh embodiment, in the same manner as for the light-emitting device 1H according to the eighth embodiment, by connecting the light-emitting diode having the lowest VF from among the three light-emitting diodes of red, green and blue in series to the other light-emitting diode to thereby adjust the VF to an equivalent value, the load voltage to each transistor can be made approximately the same. Further, the power that was being wastefully consumed inside the transistors in the case where there was only a red light-emitting diode can be effectively utilized by the light-emitting diode 2O, whereby emission efficiency can be increased. Other than orange, other diodes may be selected as the diode connected in series, such as red, yellow or the like.

Further, for the light-emitting device 1L according to the eleventh embodiment, by adding an orange light-emitting diode having a peak wavelength between that of the red and green light-emitting diodes, a wavelength discontinuous region can be filled in, whereby color rendering properties can be increased. As the added light-emitting diode, other light-emitting diodes can be employed, such as a yellow light-emitting diode or the like, other than orange, as long as such diode has a peak wavelength in between the emitted peak wavelength of the red and green light-emitting diodes. Operation of the light-emitting device 1L according to the eleventh embodiment is the same as that for the light-emitting device 1A according to the first embodiment, and is conducted in accordance with the timing chart illustrated in FIG. 5.

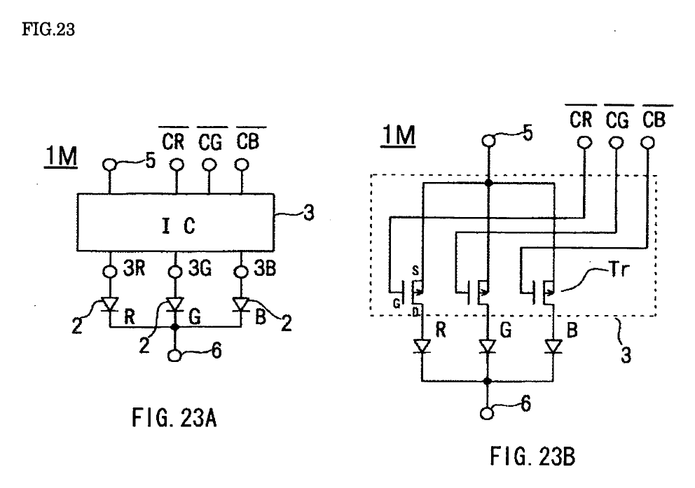

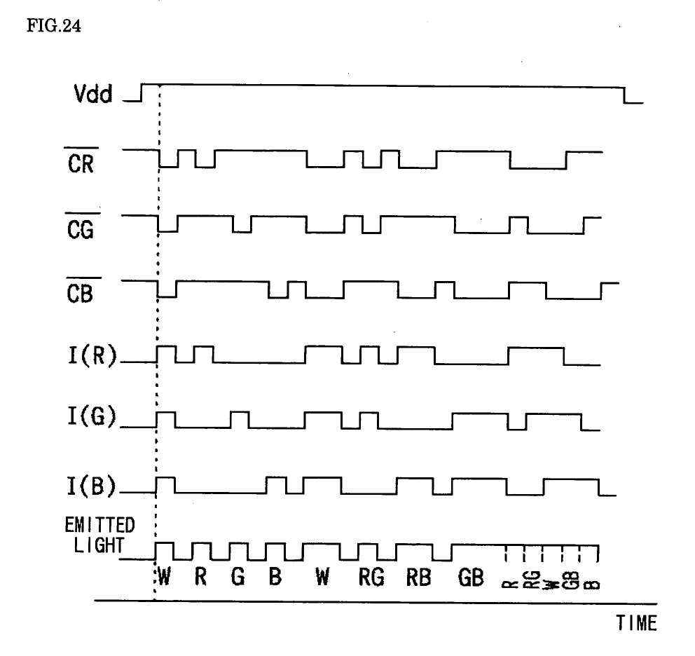

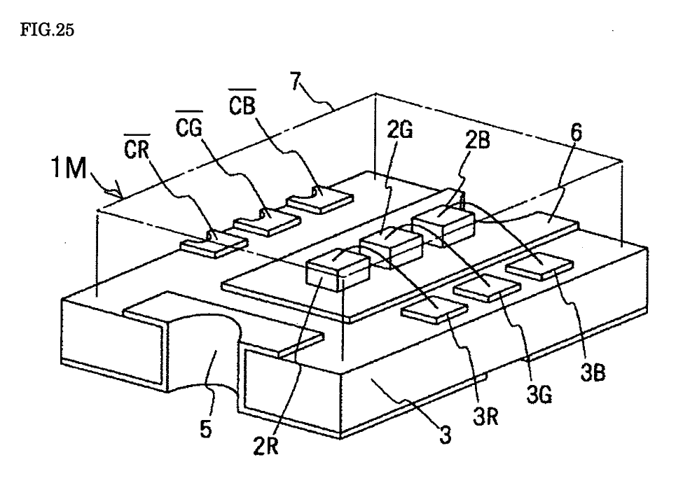

Next, a light-emitting device 1M according to a twelfth embodiment will be described with reference to FIGS. 23 to 25. While the light-emitting devices 1A to 1L of the previous embodiments were utilized as two-terminal type light-emitting devices using only the external terminals 5, 6, the light-emitting device 1M according to this twelfth embodiment includes the capability of achieving multicolor light emission in addition to white light emission. FIG. 23A is a schematic circuit diagram of the light-emitting device 1M according to the twelfth embodiment; FIG. 23B is a detailed circuit diagram of the light-emitting device 1M according to the twelfth embodiment; FIG. 24 is a timing chart illustrating the operation of the light-emitting device 1M according to the twelfth embodiment; and FIG. 25 is a perspective view as seen through the molded resin of light-emitting device 1M according to the twelfth embodiment.

The major difference between the light-emitting device 1M according to the twelfth embodiment and the light-emitting device 1A of the first embodiment is that control terminals CR, CG and CB for externally controlling the emission state of each of the light-emitting diodes 2R, 2G and 2B are provided on the drive IC 3. These control terminals CR, CG and CB are connected to the gate terminal of each of the transistors to enable each transistor to be individually controlled. Each of the transistors is configured from a P-channel MOSFET, wherein the drain terminal is connected to the anode side of the light-emitting diode. The source sides of the transistors are commonly connected, and are connected to an external terminal 5. In order to use the transistors in a reverse state, each of the control terminals CR, CG and CB is usually in a high state, and when in a low state, the terminals are used as an active low terminal so that the transistors can be made active. In FIGS. 23 to 25 a bar is drawn above CR, CG and CB to indicate active low.

As illustrated in FIG. 24, according to the above features, in a normal state where only a constant voltage Vdd is applied between the external terminals, the light-emitting device does not emit light. If all of the control terminals CR, CG and CB are set to a low state, all of the transistors are turned to an on state, and current flows to all of the light-emitting diodes. White light (W) emission is obtained by designing the drive IC (and its transistors) so that the current value of each of the light-emitting diodes can obtain white light. If only one of the control terminals CR, CG and CB is selectively set to a low state, only one of the light-emitting diodes is selectively activated, whereby light having a specific color such as R (red), G (green) or B (blue) can be obtained. By varying the combination of the control terminals CR, CG and CB that are set to a low state, an emitted color can be obtained by the mixing of a plurality of colors.

FIG. 25 illustrates one embodiment of a light-emitting device 1 which comprises such control terminals CR, CG and CB. The major differences between the light-emitting device 1M illustrated in FIG. 25 and the light-emitting device 1A of the first embodiment are that the light-emitting diodes 2 disposed on the circuit board 4 are disposed on the drive IC 3; the cathode side of the light-emitting diodes 2R, 2G and 2B is fixed by a conductive material on the terminals for the cathode formed on the surface of the drive IC 3; and the anode side of the light-emitting diodes is connected by a wire to the output terminals 3R, 3G and 3B formed on the surface of the drive IC 3.

In the present embodiment, two external terminals 5, 6 are connected to a given power source terminal, and the control terminals CR, CG and CB are connected to a given control circuit. Using such features allow white light emission operation and multicolor light emission operation from the mixing of the three colors of red, green and blue.

The drive IC 3 is usually formed from silicon. Silicon has better thermal conductivity than glass epoxy or the like, whereby heat radiating properties can be increased. Further, since the difference in thermal expansion coefficient with the semiconductor material constituting the light-emitting diodes 2 can be reduced, by disposing the light-emitting diodes on the drive IC 3, the occurrence of stress and strain which is normally caused by the thermal expansion coefficient difference can be suppressed, whereby reliability can be increased.

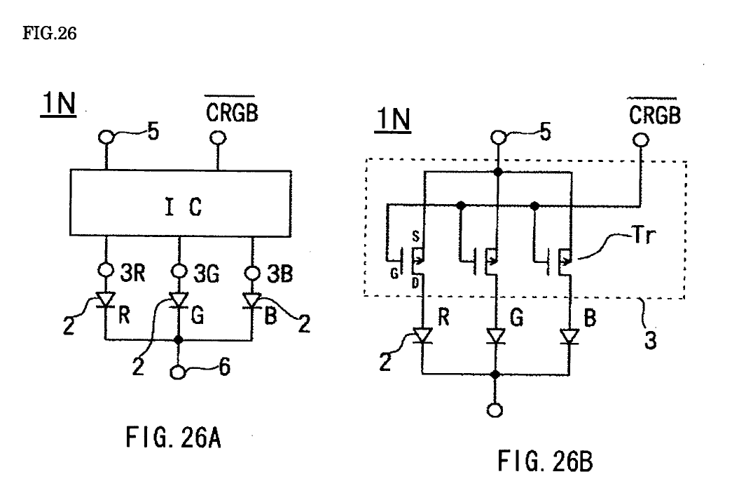

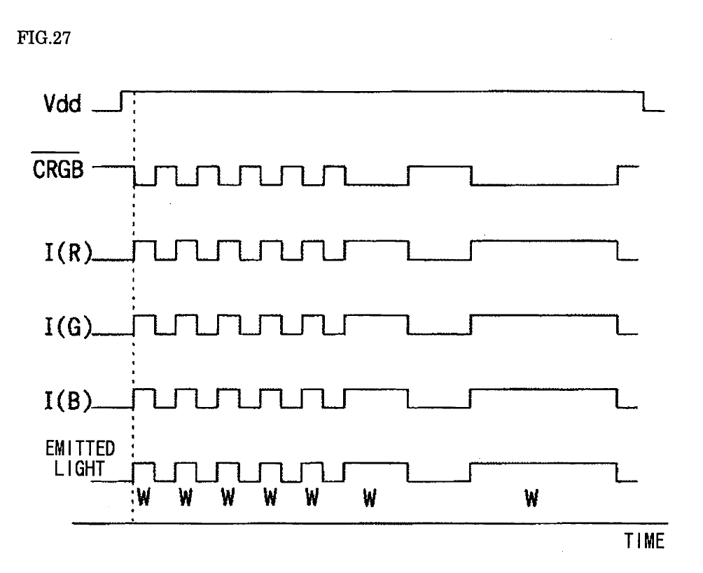

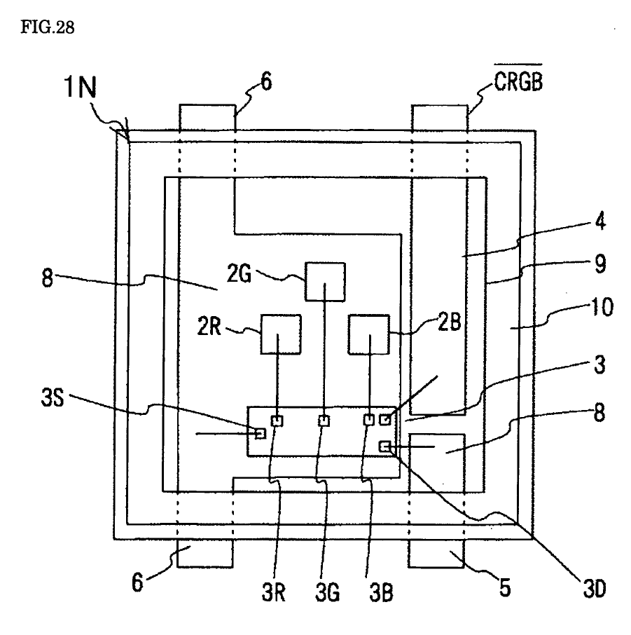

Next, a light-emitting device 1N according to a thirteenth embodiment will be described with reference to FIGS. 26 to 28. While the light-emitting device 1M of the twelfth embodiment was an embodiment in which, in addition to external terminals 5, 6, control terminals were provided corresponding to each of the light-emitting diodes, the light-emitting device 1N according to this thirteenth embodiment includes the provision of, in addition to external terminals 5, 6, a common control terminal CRGB on each of the light-emitting diodes. FIG. 26A is a schematic circuit diagram of the light-emitting device 1N according to the thirteenth embodiment; FIG. 26B is a detailed circuit diagram of the light-emitting device 1N according to the thirteenth embodiment; FIG. 27 is a timing chart illustrating the operation of the light-emitting device 1N according to the thirteenth embodiment; and FIG. 28 is a perspective view as seen through the molded resin of light-emitting device 1N according to the thirteenth embodiment.

The light-emitting device 1N according to the thirteenth embodiment has a three-terminal structure from the provision of one control terminal CRGB for externally controlling the emission state of each of the light-emitting diodes 2R, 2G and 2B on the drive IC 3. This control terminal CRGB is connected in common to each gate terminal of the transistors to enable each transistor to be simultaneously controlled. Each transistor is configured from a P-channel MOSFET, wherein the drain terminal is connected to the anode side of the light-emitting diodes. The source sides of the transistors are connected in common to an external terminal 5. In order to use the transistors in a reverse bias state, the control terminal CRGB is usually in a high state, and when in a low state, the terminal is used as an active low terminal so that the transistors can be made active. In FIGS. 26 to 28 a bar is drawn above the CRGB to indicate active low.

As illustrated in FIG. 27, according to the above features, in a normal state where only a constant voltage Vdd is applied between the external terminals, the light-emitting device 1N does not emit light. If the control terminal CRGB is set to a low state, all of the transistors are turned to an on state, and current flows to all of the light-emitting diodes 2. White light is obtained by designing the drive IC (and its transistors) so that the current value of each of the light-emitting diodes 2 can obtain white light.

FIG. 28 illustrates one embodiment of the light-emitting device 1N which comprises such a control terminal CRGB. The major difference between this light-emitting device 1N and the light-emitting device 1A of the first embodiment is that, as the circuit board 4, a board which employs a lead frame is used instead of a print-type board.

The board 4 is formed with a metal lead frame 8, in which plating was coated onto an iron or copper material, integrated with a resin 9. The lead frame 8 is configured from a plurality of frames comprising an inner section that functions as a component placement region and an outer section which functions as an external terminal, these sections being integrated with the resin 9 by a process such as insert molding. The outer section of the frame 8 is, after being cut away from the lead frame, folded as necessary onto the underside of the resin, to thereby function as the external terminals 5, 6 and control terminal CRGB. The surface of the inner section on which the light-emitting diodes 2 and drive IC 3 are supposed to be located is exposed without being covered by the resin 9. The resin 9 constituting the circuit board 4 also functions as a reflective frame which reflects the light of the light-emitting diodes 2. So as to function as a reflective frame, it is preferable to use as the resin 9 a white resin having excellent reflectivity. To increase the performance of the reflective frame, it is also preferable to provide a reflective wall 10 for reflecting light upwards in the circuit board 4 periphery. In the hollow surround by this reflective wall 10, the light-emitting device 1N is formed by providing a resin 7 for molding the light-emitting diodes 2 and the drive IC 3.

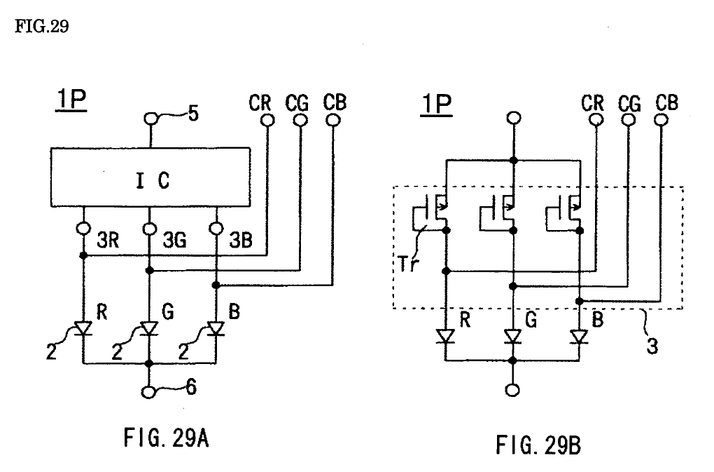

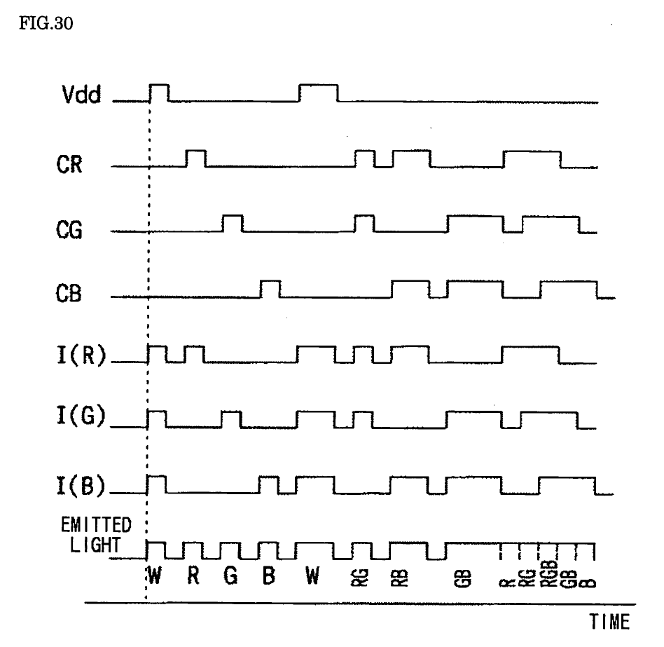

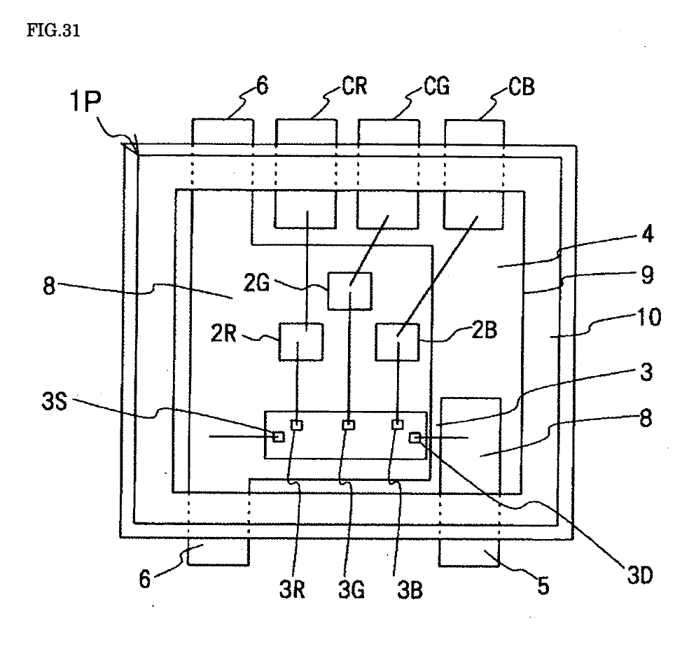

Next, a light-emitting device 1P according to a fourteenth embodiment will be described with reference to FIGS. 29 to 31. While the light-emitting device 1N of the thirteenth embodiment was an embodiment in which control terminals CR, CG and CB were provided on the drive IC 3 of the light-emitting device 1N, the light-emitting device 1P according to this fourteenth embodiment includes the control terminals CR, CG and CB for directly driving the light-emitting diodes externally being connected to a connecting portion of the drive IC and the light-emitting diodes. FIG. 29A is a schematic circuit diagram of the light-emitting device 1P according to the fourteenth embodiment; FIG. 29B is a detailed circuit diagram of the light-emitting device 1P according to the fourteenth embodiment; FIG. 30 is a timing chart illustrating the operation of the light-emitting device 1P according to the fourteenth embodiment; and FIG. 31 is a perspective view as seen through the molded resin of light-emitting device 1P according to the fourteenth embodiment.

The light-emitting device 1P according to this fourteenth embodiment provides control terminals CR, CG and CB on the light-emitting device 1P, which are connected to a connecting portion of the drive IC 3 and the respective light-emitting diodes 2R, 2G and 2B. If the light-emitting device 1P is used as a white light-emitting device, the control terminals CR, CG and CB are used in an open state. In addition, by switching the voltage Vdd applied to the external terminals on/off, the same form as that of the light-emitting device 1A of the first embodiment can be achieved.

On the other hand, if the light-emitting device 1P is used as a multicolor light-emitting device, the external terminal 5 is used in an open state. In addition, by switching the voltage applied to the control terminals CR, CG and CB between high/low, or setting the supplied current value to an arbitrary value, the light-emitting device 1P is used by switching the combined state of the emitted colors of the light-emitting diodes, or switching the emitted brightness of each of the light-emitting diodes.

Here, in the case where white light is emitted using only the external terminals (“W” is written as the emitted color), and the case where white light is emitted using only the control terminals CR, CG and CB and the terminal 6 (“RGB” is written as the emitted light color), the current value flowing through the transistors and the current value flowing through the control terminals do not always match, so that even for the same white color, there may be slight difference in hue.

FIG. 31 illustrates one embodiment of a light-emitting device 1P which comprises such control terminals CR, CG and CB. As with the light-emitting device 1N of the thirteenth embodiment, this light-emitting device 1P includes the use of a board 4 of a type which employs a lead frame.

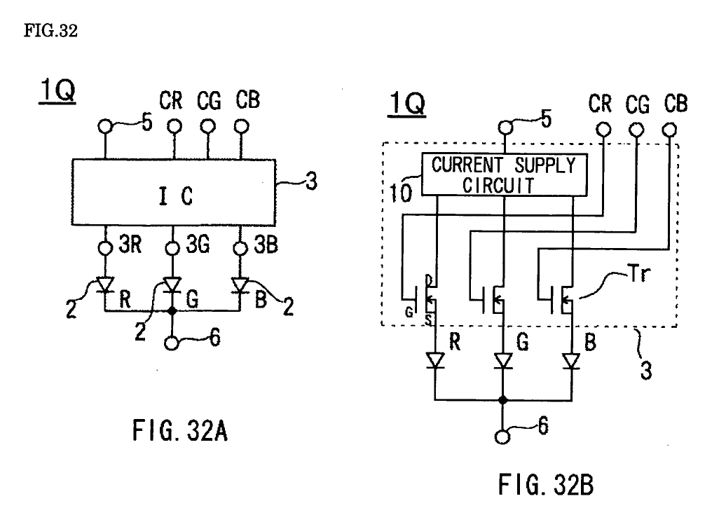

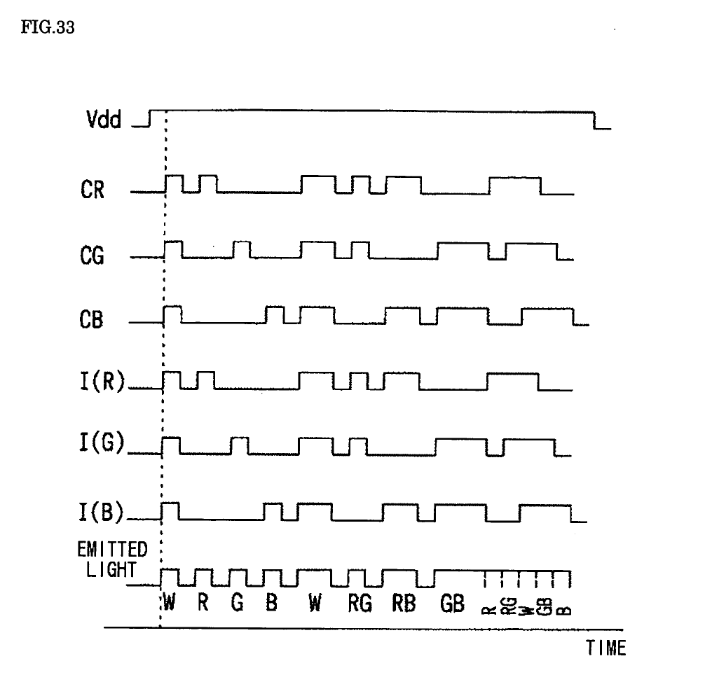

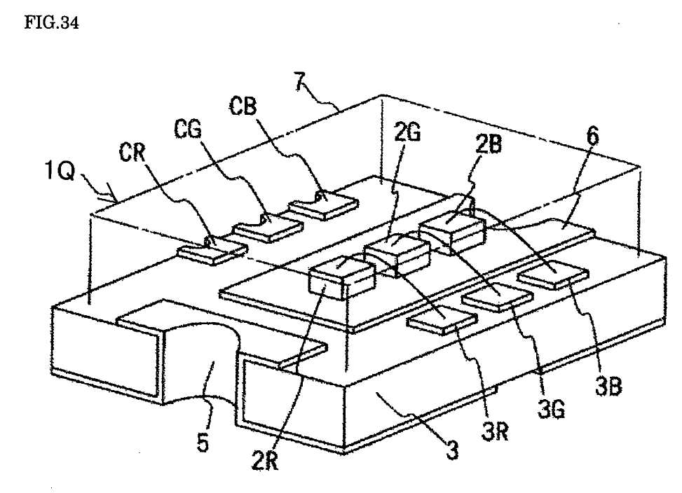

Next, a light-emitting device 1Q according to a fifteenth embodiment will be described with reference to FIGS. 32 to 34. While the light-emitting devices 1K, 1L of the above tenth and eleventh embodiments have a current supply circuit 10, and emit only white light by utilizing the light-emitting devices 1K, 1L as two-terminal devices which use only external terminals 5, 6, the light-emitting device 1Q according to the fifteenth embodiment includes the features of emitting not only white light but multicolored light as well. FIG. 32A is a schematic circuit diagram of the light-emitting device 1Q according to the fifteenth embodiment; FIG. 32B is a detailed circuit diagram of the light-emitting device 1Q according to the fifteenth embodiment; FIG. 33 is a timing chart illustrating the operation of the light-emitting device 1Q according to the fifteenth embodiment; and FIG. 34 is a perspective view as seen through the molded resin of light-emitting device 1Q according to the fifteenth embodiment.

The major difference between the light-emitting device 1Q according to the fifteenth embodiment and the light-emitting device 1K according to the tenth embodiment is that control terminals CR, CG and CB for externally controlling the emission state of each of the light-emitting diodes 2R, 2G and 2B which are provided on the drive IC 3. These control terminals CR, CG and CB are connected to the gate terminal of each transistor to enable each transistor to be individually controlled. Each transistor is configured from an N-channel MOSFET, wherein the source terminal is connected to the anode side of the light-emitting diode. The drain terminals of the transistors are connected to a current supply circuit 10. This current supply circuit 10 has the same features as that used by the light-emitting device 1K of the tenth embodiment, being configured with a constant current circuit which supplies a constant current preset for each of a plurality of transistors Tr.

In the present embodiment, which controls gate control of the transistors Tr using control terminals CR, CG and CB, there is no need to have the control circuit of the gates embedded in the current supply circuit 10, as is the case with the light-emitting device 1K of the tenth embodiment. A current supply circuit 10 embedded with a control circuit can also be used. In such a case, the gate control circuit of the current supply circuit 10 may be connected with each of the control terminals CR, CG and CB.

As illustrated in FIG. 33, according to the above features, in a normal state where only a constant voltage Vdd is applied between the external terminals, the light-emitting device does not emit light. If all of the control terminals CR, CG and CB are set to a high state, all of the transistors Tr are turned to an on state, and current flows to all of the light-emitting diodes 2. White light (W) emission is obtained by designing the drive IC (and its current supply circuit) so that the current value of each of the light-emitting diodes 2 is a value at which white light can be obtained. If only one of the control terminals CR, CG and CB is selectively set to a high state, only one of the light-emitting diodes is selectively activated, whereby light having a specific color such as R (red), G (green) or B (blue) can be obtained. By varying the combination of the control terminals CR, CG and CB that are set to a high state, an emitted color can be obtained by the mixing of a plurality of colors.

FIG. 34 illustrates one embodiment of a light-emitting device 1Q which comprises such control terminals CR, CG and CB. The major difference between this light-emitting device 1Q and the light-emitting device 1K of the tenth embodiment is that the light-emitting diodes 2 disposed on the circuit board 4 are disposed on the drive IC 3. The cathode side of the light-emitting diodes 2R, 2G and 2B is fixed by a conductive material on the terminals for the cathode formed on the surface of the drive IC 3, and the anode side of the light-emitting diodes is connected by a wire to the output terminals 3R, 3G and 3B formed on the surface of the drive IC 3.

In the present embodiment, two external terminals 5, 6 are connected to a given power source terminal, and the control terminals CR, CG and CB are connected to a given control circuit. Using such features allow white light emission operation and multicolor light emission operation from the mixing of the three colors of red, green and blue.

In addition, the control terminals CR, CG and CB may be connected in common to act as one terminal, and used only for on/off control during white light emission operation.

The drive IC 3 is usually formed from silicon. Silicon has better thermal conductivity than glass epoxy or the like, whereby heat radiating properties can be increased. Further, since the difference in thermal expansion coefficient with the semiconductor material constituting the light-emitting diodes 2 can be reduced, by disposing the light-emitting diodes on the drive IC 3, the occurrence of stress and strain normally caused by the thermal expansion coefficient difference can be suppressed, whereby reliability can be increased.

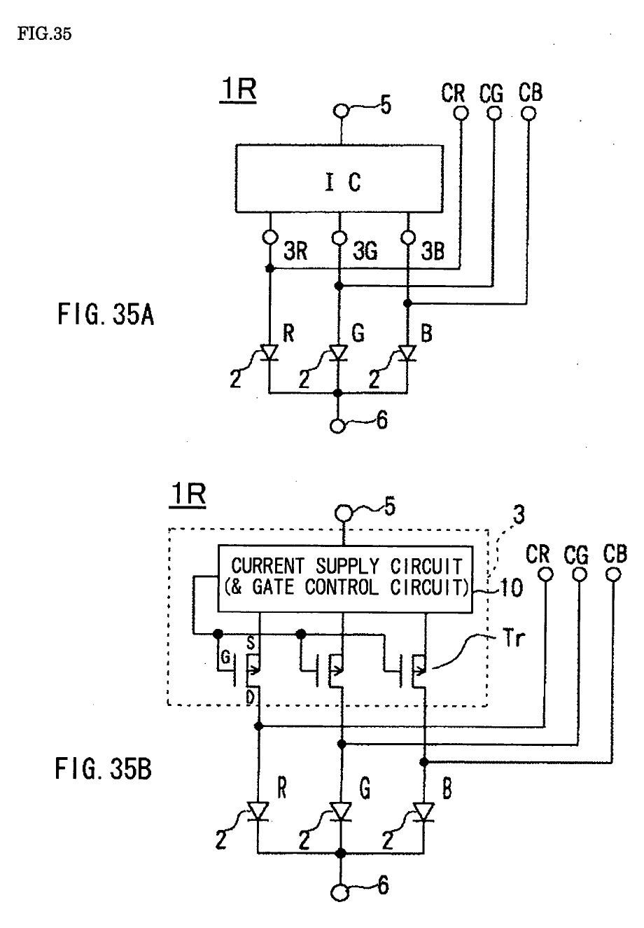

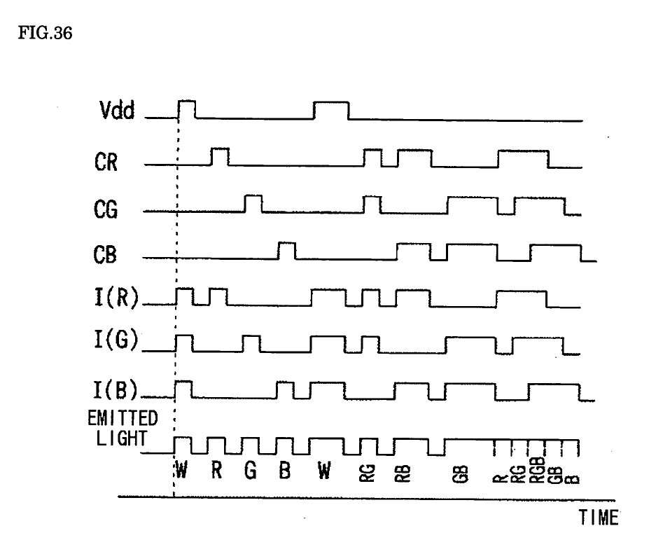

Next, a light-emitting device 1R according to a sixteenth embodiment will be described with reference to FIGS. 35 and 36.

While the light-emitting device 1Q according to the fifteenth embodiment provides control terminals CR, CG and CB on the drive IC 3 of the light-emitting device 1Q, the light-emitting device 1R according to the sixteenth embodiment includes the control terminals CR, CG and CB for directly driving the light-emitting diodes 2 externally being connected to a connecting portion of the drive IC 3 and the light-emitting diodes 2. FIG. 35A is a schematic circuit diagram of the light-emitting device 1R according to the sixteenth embodiment; FIG. 35B is a detailed circuit diagram of the light-emitting device 1R according to the sixteenth embodiment; and FIG. 36 is a timing chart illustrating the operation of the light-emitting device 1R according to the sixteenth embodiment.

The light-emitting device 1R according to this sixteenth embodiment provides control terminals CR, CG and CB on the light-emitting device 1R, which are connected to a connecting portion of the drive IC 3 and the respective light-emitting diodes 2R, 2G and 2B. If the light-emitting device 1 is used as a white-light light-emitting device, the control terminals CR, CG and CB are used in an open state. In addition, as illustrated in FIG. 36, by switching the voltage Vdd applied to the external terminals on/off, the same form as that of the light-emitting device 1Q of the fifteenth embodiment can be achieved.

On the other hand, if the light-emitting device 1R is used as a multicolor light-emitting device, the external terminal 5 is used in an open state. In addition, by switching the voltage applied to the control terminals CR, CG and CB between high/low, or setting the supplied current value to an arbitrary value, the light-emitting device 1R is used by switching the combined state of the emitted colors of the light-emitting diodes, or switching the emitted brightness of each of the light-emitting diodes.

Here, in the case where white light is emitted using only the external terminals 5, 6 (“W” is written as the emitted light color), and the case where white light is emitted using only the control terminals CR, CG and CB and the terminal 6 (“RGB” is written as the emitted light color), the current value flowing through the transistors Tr and the current value flowing through the control terminals CR, CG and CB do not always match, so that even for the same white color, there may be slight difference in hue.

It is noted that a perspective view as seen through the molded resin of the light-emitting device 1R according to the sixteenth embodiment is the same as that of the light-emitting device 1P according to the fourteenth embodiment illustrated in FIG. 31.

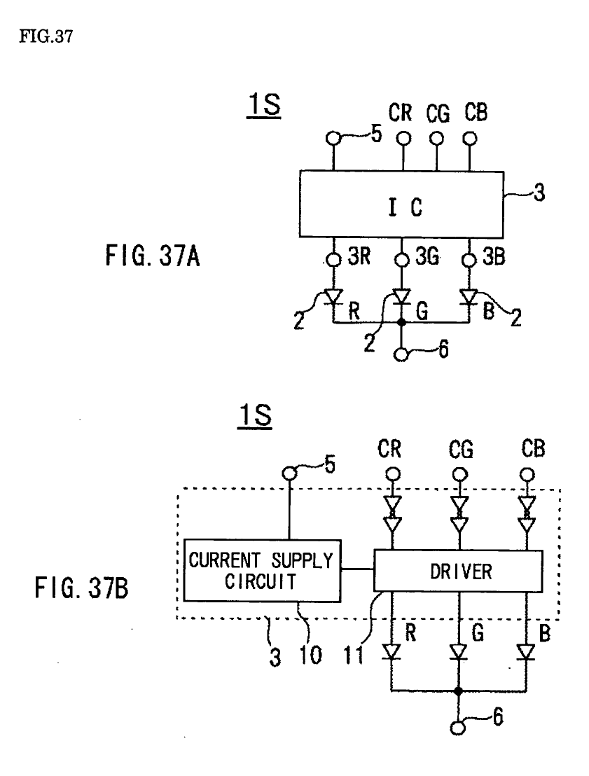

Next, a light-emitting device 1S according to a seventeenth embodiment will be described with reference to FIGS. 37A and 37B. FIG. 37A is a schematic circuit diagram of the light-emitting device 1S according to the seventeenth embodiment; and FIG. 37B is a detailed circuit diagram of the light-emitting device 1S according to the seventeenth embodiment. The light-emitting device 1S according to the seventeenth embodiment has the same basic features as the light-emitting device 1Q of the fifteenth embodiment, and thus explanation will focus on the portions that are different. The difference between the light-emitting device 1S according to the seventeenth embodiment and the light-emitting device 1Q of the fifteenth embodiment is the internal configuration of the drive IC 3, which comprises a power supply circuit 10, a driver 11, and an inverter for signal control of the external terminals which controls opening/closing of a driver 11.

This driver 11 is configured from a plurality of constant current circuits for supplying a constant current value preset for each of the light-emitting diodes, based on a constant current supplied from the power supply circuit 10. In the present embodiment, in which the number of connecting light-emitting diodes is three (three outputs), three constant current circuits are embedded. However, the number of embedded constant current circuits can be increased in accordance with the number of outputs.

Control signals from the control terminals CR, CG and CB are applied to the driver 11 by passing through two inverters. The illumination state of the light-emitting diodes is controlled by the signals applied to the control terminals CR, CG and CB. Operation of the light-emitting device 1S according to the seventeenth embodiment is the same as operation of the light-emitting device 1Q of the fifteenth embodiment (FIG. 33).

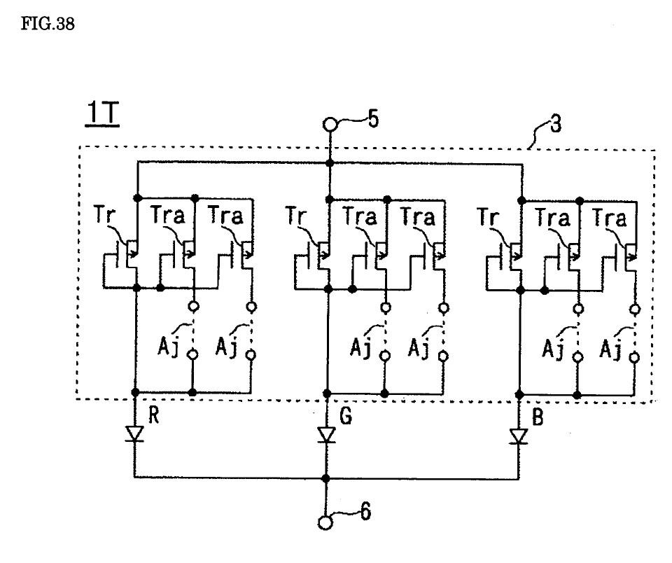

Next, a light-emitting device 1T according to an eighteenth embodiment will be described with reference to FIG. 38. FIG. 38 is a detailed circuit diagram of the light-emitting device 1T according to the eighteenth embodiment. The light-emitting device 1T according to this eighteenth embodiment has the same basic features as the light-emitting device 1A of the first embodiment, and thus explanation will focus on the portions that are different. The difference between the light-emitting device 1T according to the eighteenth embodiment and the light-emitting device 1A according to the first embodiment is the internal configuration of the drive IC 3, in which a fine-tuning circuit is added that allows the current value applied to each of the light-emitting diodes to be fine-tuned.

This fine-tuning circuit is connected with a transistor Tra for current correction connected in parallel to the basic transistors Tr. While two transistors Tra for current correction are used in the present embodiment, one may be used, and three or more may be used. When using plural transistors Tra for current correction, the configuration of each of the transistors Tra for current correction may be made the same or may be made different.

The transistors Tra for current correction preferably have a smaller current capacity than the basic transistors Tr, although the transistors Tra for current correction may have the same configuration, and thus the same current capacity, as the basic transistors Tr.

Although the number of transistors Tra for current correction is set as the same as the number of connecting light-emitting diodes, the number may be changed depending on the characteristics of the light-emitting diodes.

While the basic transistors Tr have a different configuration (surface area etc.) for each of the light-emitting diodes for setting the current ratio of the light-emitting diodes, the basic transistors Tr may all be made to have the same configuration. The basic transistors Tr and the transistors Tra for current correction may be configured as a pair, or may all have the same configuration regardless of the light-emitting diode.

The transistors Tra for current correction comprise at a part thereof a disconnection region Aj which is utilized in disconnecting the current pathway. This disconnection region Aj can be disconnected by laser trimming, zapping (thermal cutting) or similar technique. In order to carry out laser trimming, the disconnection region Aj is preferably provided on the surface of the drive IC 3.

By carrying out such a laser trimming, zapping or similar technique, the current flowing in the transistors Tra for current correction can be blocked, thereby allowing the current amount flowing in the light-emitting diodes 2 to be adjusted.

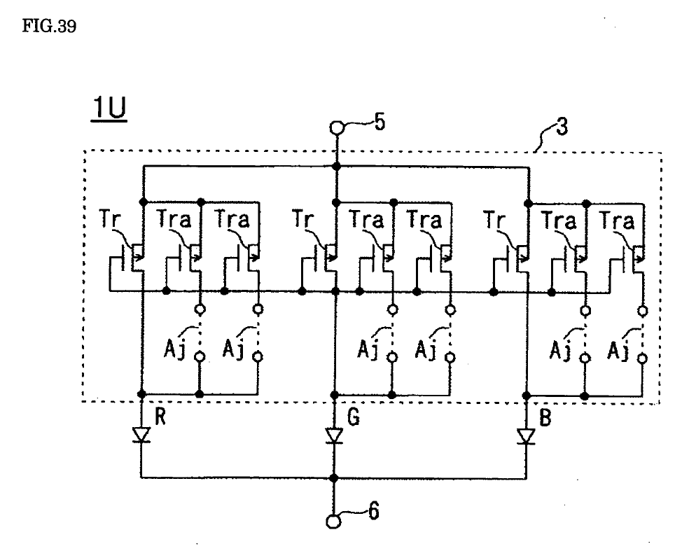

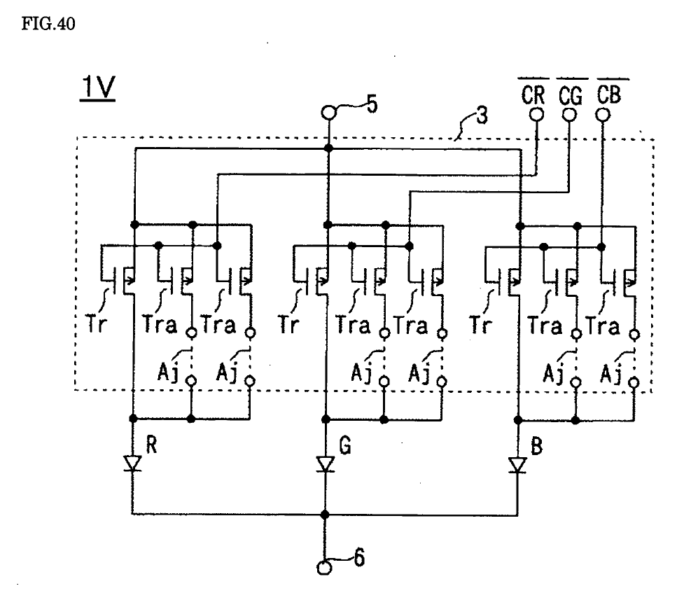

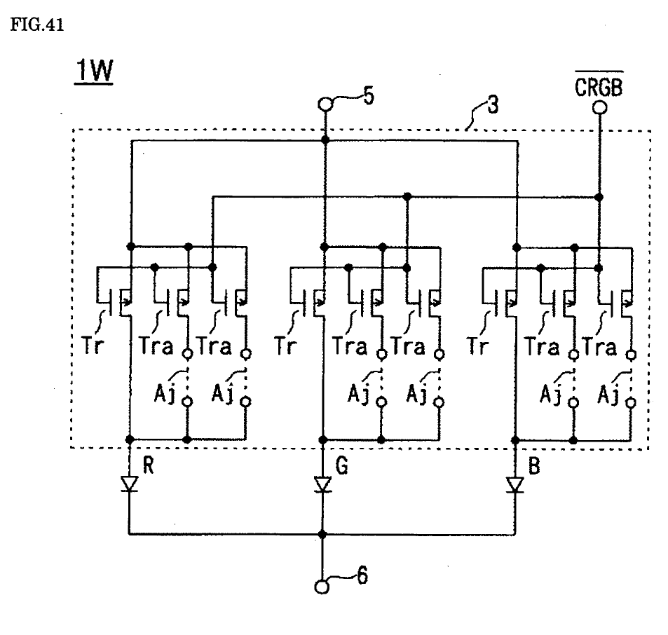

The fine-tuning circuit used in the eighteenth embodiment can also be applied in each of the above-described embodiments. The light-emitting device 1U of FIG. 39 illustrates an embodiment in which a fine-tuning circuit is used in the light-emitting device 1G of the seventh embodiment illustrated in FIG. 17; the light-emitting device 1V of FIG. 40 illustrates an embodiment in which a fine-tuning circuit is used in the light-emitting device 1M of the twelfth embodiment illustrated in FIG. 23; and the light-emitting device 1W of FIG. 41 illustrates an embodiment in which a fine-tuning circuit is used in the light-emitting device 1N of the thirteenth embodiment illustrated in FIG. 26.

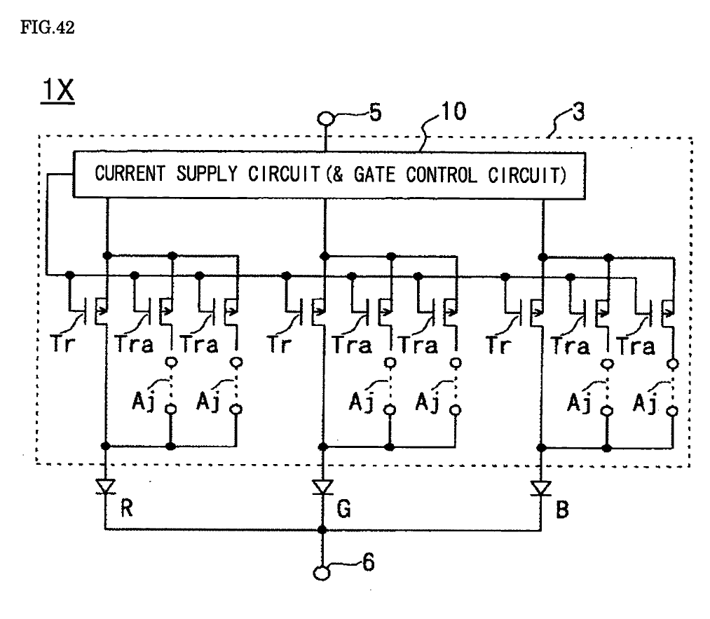

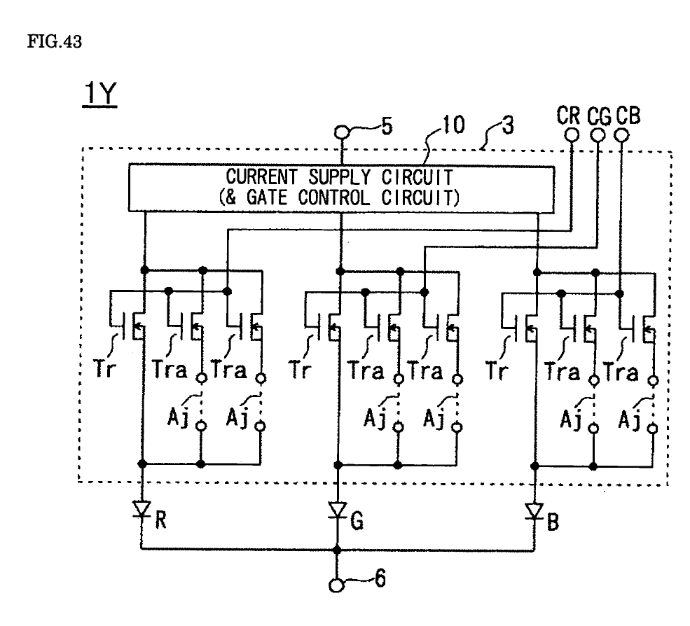

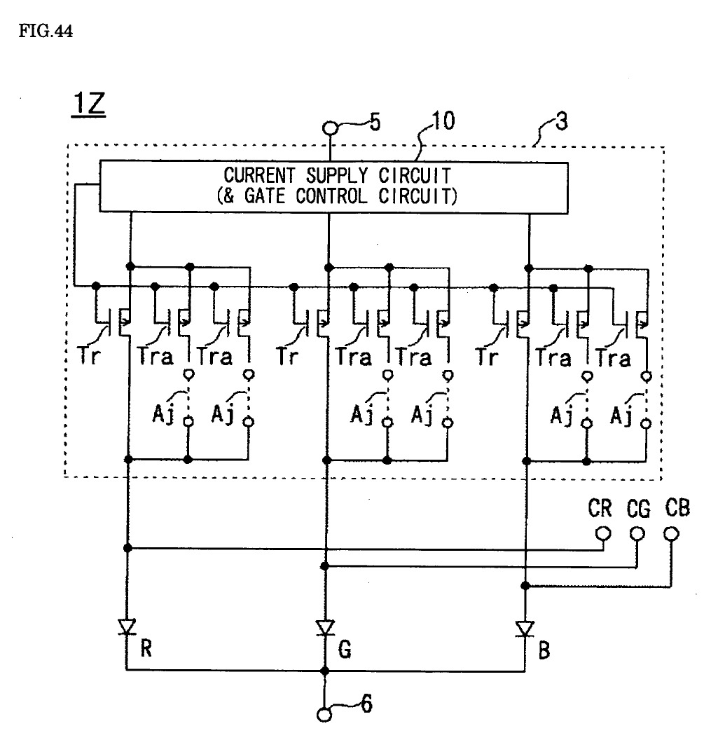

Further, the light-emitting device 1X of FIG. 42 illustrates an embodiment in which a fine-tuning circuit is used in the light-emitting device 1K of the tenth embodiment illustrated in FIG. 21; the light-emitting device 1Y of FIG. 43 illustrates an embodiment in which a fine-tuning circuit is used in the light-emitting device 1Q of the fifteenth embodiment illustrated in FIG. 32; and the light-emitting device 1Z of FIG. 44 illustrates an embodiment in which a fine-tuning circuit is used in the light-emitting device 1R of the sixteenth embodiment illustrated in FIG. 35.

The embodiments according to the above-described fine-tuning illustrate cases where the current value is restricted by disconnecting the transistors Tra circuit, which is normally connected, with a disconnecting region Aj. On the other hand, it is also possible to have a form in which the current value is made to increase by connecting with an open region. For example, also acceptable is a form wherein the disconnection region Aj is made in advance an open state, and that portion is electrically connected using a conductive material (solder, wire or the like).

In addition, while the above-described embodiments used a MOS-type transistor for the transistors Tr, a bipolar-type transistor can also be used. In such a case, a base can substitute for the gate, an emitter can substitute for the source, and a collector can substitute for the drain.

If a bipolar-type transistor is used, the fine-tuning circuit can be provided in the region for setting the transistor gain. Further, the base current can be, for example, varied by laser trimming and zapping.

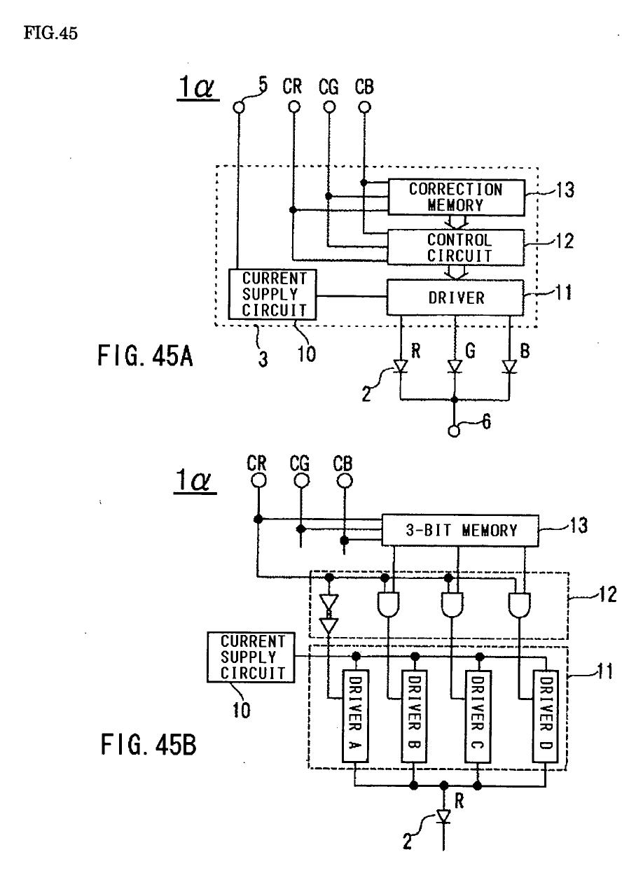

Next, a light-emitting device 11a of a nineteenth embodiment embedded with a circuit for fine-tuning output current will be described with reference to FIG. 45. The basic features of the light-emitting device 1α of this nineteenth embodiment is the same as that of the light-emitting device 1S of the seventeenth embodiment illustrated in FIG. 37, although light-emitting device 1α includes slight differences in the features of the driver 11 and control circuit 12 which controls the driver 11, and in the addition of a memory 13 for correction.

FIG. 45A is a circuit diagram of the light-emitting device 1α of the nineteenth embodiment corresponding to FIG. 37B; and FIG. 45B is a circuit diagram illustrating the details of the portion relating to one light-emitting diode (in the present embodiment, the red light-emitting diode 2R).

As illustrated in FIG. 45B, the driver 11 comprises drivers B, C and D for correction in addition to the basic driver A. The drivers A to D are configured from constant current circuits which receive a constant current supply from a constant supply circuit 10 and output a preset current value. The drivers A to D can be set so that multiple different current values are output, such as 10 mA for the basic driver A, 5 mA for the driver B for correction, 0.3 mA for the driver C for correction, and 2 mA for the driver D for correction. Control of each of the drivers A to D is performed by a control circuit 12. The control circuit 12 controls each of the drivers A to D based on control terminal CR data and 3-bit data stored in a correction memory. The basic driver A is activated by a signal applied through two inverters when the control terminal CR is in a high state, and outputs 10 mA. The drivers B to D are activated by data stored in the memory and by a signal after an AND operation conducted by an AND circuit, when the control terminal CR is in a high state, and outputs 5, 3 and 2 mA. The outputs of each of the drivers A to D are added together, and applied to the light-emitting diode 2R. Therefore, by variously setting the values of the data for correction stored in the memory 13, the current values applied to the light-emitting diode can be varied. In the present embodiment, the current values can be varied in the range of 10 to 20 mA. The number of drivers for correction can be variously changed, and the configuration of the control circuits and memory can be adapted with such changes.

The circuits for the green and blue light-emitting diodes 2G, 2B (i.e. those other than red) have the same circuit as that illustrated in FIG. 45B.

The correction memory 13 is configured from a non-volatile memory which stores respective 3-bit correction data corresponding to each of the light-emitting diodes. The 3-bit-configured correction data can be written in advance through the control terminals CR, CG and CB.

Operation of the light-emitting device 1α of the nineteenth embodiment is the same as that for the light-emitting device 1Q of the fifteenth embodiment illustrated in FIG. 33.

While the above embodiments were illustrated using respectively one of each of the red, green and blue light-emitting diodes, each light-emitting diode color is not limited to one, and a plurality can be used.

Further, to obtain white light, in addition to the light-emitting diodes of the three primary colors, a light-emitting diode having an emitted color other than the three primary colors, e.g. blue-green, orange and yellow, can be added, so that a configuration of four colors or more is possible. As illustrated in FIG. 5, by connecting a light-emitting diode that should be added in series to the light-emitting diode having the lowest VF, not only are the color rendering properties increased but the power that would be wastefully consumed by the transistors can be decreased, whereby emission efficiency can be increased.

Moreover, to obtain white light, a combination of emitted colors other than the three primary colors of red, green and blue can also be used. For example, combinations of plural complementary light-emitting diodes, such as a combination of blue and yellow, a combination of blue-green and orange, or other such combinations, can also be used. Using such combinations allows the number of light-emitting diodes to be reduced.

The above embodiments can also be applied to white or pseudo-white which is close to white.

In a light-emitting device which emits orange by combining different colors, such as by combining red and green light-emitting diodes, the above embodiments can also be applied to two-terminal or three-or-greater-terminal light-emitting devices in which it is desired to pre-adjust the emission state of each of the light-emitting diodes according to current efficiency in cases of adjusting such emitted color or the like.

Further, in a light-emitting device which comprises a plurality of light-emitting diodes of the same color, the above embodiments can also be applied to two-terminal or three-or-greater-terminal light-emitting devices in which it is desired to pre-adjust the emission state of each of the light-emitting diodes according to current efficiency in cases of varying the emission characteristics, such as the directionality for brightening the emission state of some of the plurality of light-emitting diodes and darkening the emission state of the other light-emitting diodes.

### INDUSTRIAL APPLICABILITY

The present invention can be applied to a white, full-color, multicolor, mono-color or other such light-emitting device.

1. A light-emitting device, comprising:
a plurality of light-emitting diodes, and
a drive integrated circuit (IC) integrated with said light-emitting diodes to drive said light-emitting diodes, said drive IC being embedded with a circuit for controlling at a constant level a current value for each of said light-emitting diodes connected in series to a plurality of transistors or a constant current ratio among said light-emitting diodes.

2. The light-emitting device according to claim 1, wherein said plurality of light-emitting diodes comprise emitted colors capable of forming white light by mixing light beams thereof.

3. The light-emitting device according to claim 2, wherein said plurality of light-emitting diodes comprise emitted colors of primary colors red, green and blue.

4. The light-emitting device according to claim 2, wherein said plurality of light-emitting diodes comprise emitted colors having a complementary relationship.

5. The light-emitting device according to claim 1, wherein said plurality of light-emitting diodes comprise different emitted colors.

6. The light-emitting device according to claim 1, wherein said plurality of light-emitting diodes comprise an identical emitted color.

7. The light-emitting device according to claim 1, wherein at least two of said plurality of light-emitting diodes are connected in series.

8. The light-emitting device according to claim 7, wherein said at least two light-emitting diodes connected in series comprise an identical color or a different color selected from among red, orange, and yellow light-emitting diodes.

9. (canceled)

10. The light-emitting device according to claim 1, wherein field effect transistors or bipolar transistors are used for said transistors of said drive IC.

11. The light-emitting device according to claim 10, wherein gate terminals or base terminals of said transistors of said drive IC are commonly connected.

12. The light-emitting device according to claim 11, wherein said gate terminals or base terminals of said transistors of said drive IC are commonly connected to wiring of a light-emitting diode having a highest VF voltage among each of said light-emitting diodes whose current value or current ratio has been adjusted.

13. The light-emitting device according to claim 1, wherein said light-emitting device is a two-terminal device which comprises only said two external terminals as terminals connecting externally.

14. The light-emitting device according to claim 13, wherein said drive IC is embedded with a circuit for controlling current value for each of said plurality of light-emitting diodes at a constant level even if voltage applied between said two external terminals fluctuates.

15. The light-emitting device according to claim 1, wherein said drive IC comprises external terminals.

16. The light-emitting device according to claim 15, wherein said external terminals are control terminals for varying a current value or current ratio for each of said plurality of light-emitting diodes.

17. The light-emitting device according to claim 16, wherein said external terminals are connected to a gate terminal or base terminal of a transistor of said drive IC, for allowing a current flowing in each of said light-emitting diodes to be externally controlled.

18. The light-emitting device according to claim 17, wherein said external terminals are commonly connected to a gate terminal or base terminal of a transistor of said drive IC, for allowing a current flowing in each of said light-emitting diodes to be externally controlled with an identical timing.

19. The light-emitting device according to claim 15, wherein said external terminals, without any relationship to driving of a transistor of said drive IC, are connected individually and controllably with each of said light-emitting diodes.

20. The light-emitting device according to claim 15, wherein said drive IC comprises a current supply circuit for supplying a standard current, and a driver circuit which receives a current supply from said current supply circuit for supplying a current which is set for each of said light-emitting diodes, and wherein said external terminals are connected so that operation of said driver circuit are externally controlled.

21. The light-emitting device according to claim 16, wherein said drive IC comprises a function for fine-tuning a current value for each of said plurality of light-emitting diodes or a current ratio for each of said light-emitting diodes.

22. The light-emitting device according to claim 21, wherein said drive IC comprises a non-volatile memory for storing correction data, and a control circuit for controlling operation of said driver circuit based on data stored in said memory and data sent from said external terminals.

23. The light-emitting device according to claim 22, wherein said drive IC fine-tunes a current value for each of said plurality of light-emitting diodes based on data stored in said memory.

24. The light-emitting device according to claim 21, wherein said fine-tuning is performed by laser trimming a disconnection region provided on a surface of said drive IC, or performed by zapping a disconnection region provided inside said drive IC.

25. The light-emitting device according to claim 21, wherein said fine-tuning is performed by selecting whether a wire bond is present or not with respect to one or more wire bond terminals provided on a surface of said drive IC.

26. The light-emitting device according to claim 1, wherein said plurality of light-emitting diodes and said drive IC are mounted on a circuit board.

27. The light-emitting device according to claim 1, wherein said plurality of light-emitting diodes are disposed on said drive IC.

28. The light-emitting device according to any of claims 1 to 3, wherein said plurality of light-emitting diodes and said drive IC are covered by an identical resin.
